(19) United States
(12) Patent Application Publication
(10) Pub. No.: US 2026/0026288 A1
(43) Pub. Date: Jan. 22, 2026

(54) SYSTEM AND METHOD FOR REDUCING ELECTRICAL POWER CONSUMPTION OF HOT PLATE

(71) Applicant: Tokyo Electron Limited, Tokyo (JP)

(72) Inventors: Michael Carcasi, Austin, TX (US); Lior Huli, Albany, NY (US)

(21) Appl. No.: 18/776,821

(22) Filed: Jul. 18, 2024

(51) Int. Cl. H01L 21/67; H01L 21/324

(52) U.S. Cl. CPC H01L 21/67109; H01L 21/324; H01L 21/67253

(57) ABSTRACT

A method includes receiving a first notification that a process chamber of a baking apparatus entered an idle state, determining that a low-flow-rate (LFR) mode can be started, and providing an incoming gas to the process chamber. The incoming gas includes a first portion of a supply gas. The method further includes setting a flow rate of the incoming gas to an idle incoming flow rate, receiving a second notification that the process chamber entered an active state, determining that a high-flow-rate (HFR) mode can be started, and setting the flow rate of the incoming gas to a process incoming flow rate. The process incoming flow rate is greater than the idle incoming flow rate.

### TECHNICAL FIELD

The present disclosure relates generally to systems and methods for processing a substrate and, in particular embodiments, to a system and method for reducing electrical power consumption of a baking apparatus that includes a hot plate.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Various baking processes may be performed on the semiconductor substrate while fabricating the semiconductor device. Generally, a baking process is performed by a baking apparatus that may include a hot plate. Continuous air flow across an idle hot plate of the baking apparatus wastes electrical power due to the heat energy being swept away by the air flow and the power required to maintain the hot plate at the target process temperature.

### SUMMARY

In accordance with an embodiment of the present disclosure, an apparatus includes a process chamber, a hot plate within the process chamber, and a first valve coupled to the process chamber. The first valve is configured to control a flow rate of an incoming gas entering the process chamber. The incoming gas includes a first portion of a supply gas. The apparatus further includes a controller operably coupled to the process chamber and the first valve. The controller includes a memory configured to store a process incoming flow rate and an idle incoming flow rate. The idle incoming flow rate is less than the process incoming flow rate. The controller further includes a processor operably coupled to the memory. The processor is configured to receive a first notification that the process chamber entered an idle state, determine that a low-flow-rate (LFR) mode can be started, send a first instruction to the first valve to set the flow rate of the incoming gas to the idle incoming flow rate, receive a second notification that the process chamber entered an active state, determine that a high-flow-rate (HFR) mode can be started, and send a second instruction to the first valve to set the flow rate of the incoming gas to the process incoming flow rate.

In accordance with another embodiment of the present disclosure, an apparatus includes a first baking apparatus. The first baking apparatus includes a first process chamber, a first hot plate within the first process chamber, and a first valve coupled to the first process chamber. The first valve is configured to control a flow rate of a first incoming gas entering the first process chamber. The first incoming gas includes a first portion of a first supply gas. The first baking apparatus further includes a first controller operably coupled to the first process chamber and the first valve. The first controller is configured to receive a first notification that the first process chamber entered a first idle state, determine a first time that passed since the first process chamber entered the first idle state, and in response to determining that the first time is equal to a first threshold time: determine that a first low-flow-rate (LFR) mode can be started, send a first instruction to the first valve to set the flow rate of the first incoming gas to a first idle incoming flow rate, receive a second notification that the first process chamber entered a first active state, determine that a first high-flow-rate (HFR) mode can be started, and send a second instruction to the first valve to set the flow rate of the first incoming gas to a first process incoming flow rate. The apparatus further includes a second baking apparatus. The second baking apparatus includes a second process chamber, a second hot plate within the second process chamber, and a second valve coupled to the second process chamber. The second valve is configured to control a flow rate of a second incoming gas entering the second process chamber. The second incoming gas includes a first portion of a second supply gas. The second baking apparatus further includes a gas sensor coupled to the second process chamber. The gas sensor is configured to detect a concentration of process byproduct chemicals in a second outgoing gas leaving the second process chamber. The second baking apparatus further includes a second controller operably coupled to the second process chamber, the second valve and the gas sensor. The second controller is configured to receive a third notification that the second process chamber entered a second idle state, receive a signal from the gas sensor, determine the concentration of the process byproduct chemicals the second outgoing gas based on the signal, in response to determining that the concentration is less than or equal to a threshold concentration: determine that a second LFR mode can be started, send a third instruction to the second valve to set the flow rate of the second incoming gas to a second idle incoming flow rate, receive a fourth notification that the second process chamber entered a second active state; determine that a second HFR mode can be started; and send a fourth instruction to the second valve to set the flow rate of the second incoming gas to a second process incoming flow rate.

In accordance with yet another embodiment of the present disclosure, a method includes receiving a first notification that a process chamber of a baking apparatus entered an idle state, determining that a low-flow-rate (LFR) mode can be started, and providing an incoming gas to the process chamber. The incoming gas includes a first portion of a supply gas. The method further includes setting a flow rate of the incoming gas to an idle incoming flow rate, receiving a second notification that the process chamber entered an active state, determining that a high-flow-rate (HFR) mode can be started, and setting the flow rate of the incoming gas to a process incoming flow rate. The process incoming flow rate is greater than the idle incoming flow rate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a schematic view of a baking apparatus in accordance with various embodiments;

FIG. 1B is a schematic view of a baking apparatus in accordance with various embodiments;

FIG. 2A illustrates a cross-sectional view of a back plate in accordance with various embodiments;

FIG. 2B illustrates a cross-sectional view of a back plate in accordance with various embodiments;

FIGS. 3A and 3B illustrate perspective and cross-sectionals view of a wafer in accordance with various embodiments;

FIG. 4 illustrates a diagram showing a dependence of a concentration of process byproduct chemicals on time while performing a baking process in accordance with various embodiments;

FIGS. 5A and 5B illustrate a flow diagram of a method for reducing electrical consumption of a hot plate in accordance with various embodiments;

FIG. 6A is a schematic view of a baking apparatus in accordance with various embodiments;

FIG. 6B is a schematic view of a baking apparatus in accordance with various embodiments;

FIGS. 7A and 7B illustrate a flow diagram of a method for reducing electrical consumption of a hot plate in accordance with various embodiments;

FIG. 8 is a schematic view of a baking apparatus in accordance with various embodiments;

FIGS. 9A and 9B illustrate a flow diagram of a method for reducing electrical consumption of a hot plate in accordance with various embodiments;

FIG. 10 is a schematic view of a baking apparatus in accordance with various embodiments;

FIGS. 11A and 11B illustrate a flow diagram of a method for reducing electrical consumption of a hot plate in accordance with various embodiments;

FIG. 12 is a schematic view of a baking apparatus in accordance with various embodiments; and

FIG. 13 is a schematic view of a baking apparatus in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Continuous air flow across an idle hot plate of a baking apparatus wastes electrical power due to heat energy being swept away by the air flow and the power required to maintain the hot plate at the target process temperature. The electrical power consumption may be reduced by a thermal cycling in which electrical power is cut-off to a baking apparatus and the hot plate ramps down to ambient conditions (e.g., ambient temperature). The thermal cycling may face various issues such as (1) reduction of throughput of the baking apparatus due to ramping the hot plate back up to the process temperature, (2) potential particle concerns due to regions of the baking apparatus having different coefficient of thermal expansions (CTEs) rubbing against each other during the thermal cycling, and (3) reduction of lifetime of various parts of the baking apparatus.

The present disclosure describes an electrical power reduction process by reducing an air flow rate across a hot plate during the idle state of the baking apparatus while maintaining the target process temperature of the hot plate. In some embodiments, the baking apparatus may be configured to switch between a high-flow-rate (HFR) mode and a low-flow-rate (LFR) mode. The baking apparatus is configured to perform a baking process during the active state. The baking apparatus is set to the HFR mode during the active state. The baking apparatus is configured to perform the baking process on one or more wafers until the baking apparatus enters the idle state. In response to receiving a notification that the baking apparatus has entered the idle state, the baking apparatus may be switched to the LFR mode with a reduced air flow rate (also referred to as an idle air flow rate) after lapsing a configurable time since receiving the notification or by using a gas sensor for making a determination when to switch the baking apparatus to the LFR mode. The baking apparatus may stay in the LFR mode until a notification that the baking apparatus has entered the active state. In response to receiving the notification that the baking apparatus has entered the active state, the baking apparatus may be switched to the HFR mode with a higher air flow rate (also referred to as a process air flow rate). After entering the HFR mode, the baking apparatus is configured to process one or more additional wafers.

In some embodiments, the LFR mode of the baking apparatus may be set by using a valve that controls an air flow rate across the hot plate. In some embodiments, the valve may be a two-stage valve that can be switched between high and low air flow modes. The use of the valve may induce some fluctuations in the air supply or system exhaust conditions. To mitigate fluctuations in the air supply or system exhaust conditions, in some embodiments, a fabrication facility air may be pulled into the exhaust system to offset the low air flow rate in the exhaust system.

In other embodiments, the LFR mode of the baking apparatus may be set by using a partial bypass system (e.g., including two valves and a bypass conduit that connects an air supply conduit to an exhaust conduit) to divert a portion of the supply air to the exhaust conduit leading to a reduced air flow rate across the hot plate. By using the partial bypass system, fluctuations in the air supply or system exhaust conditions may be reduced or avoided.

Various embodiments of the present disclosure achieve various advantages. One or more embodiments allow for avoiding thermal cycling of a baking apparatus and reducing or avoiding issues caused by the thermal cycling. One or more embodiments further allow for reducing electrical power consumption of the baking apparatus by reducing an air flow rate across a hot plate during the idle process while keeping the hot plate at the target process temperature.

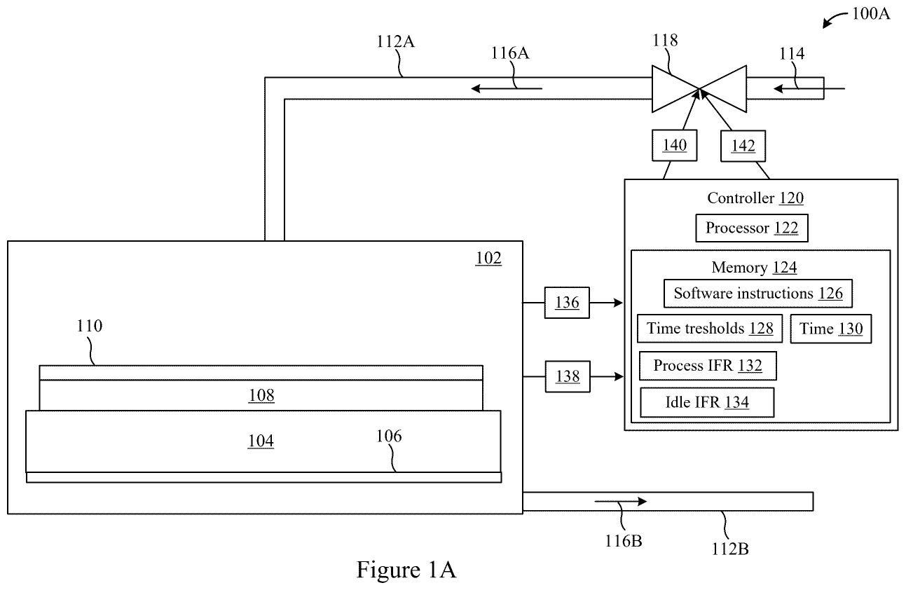

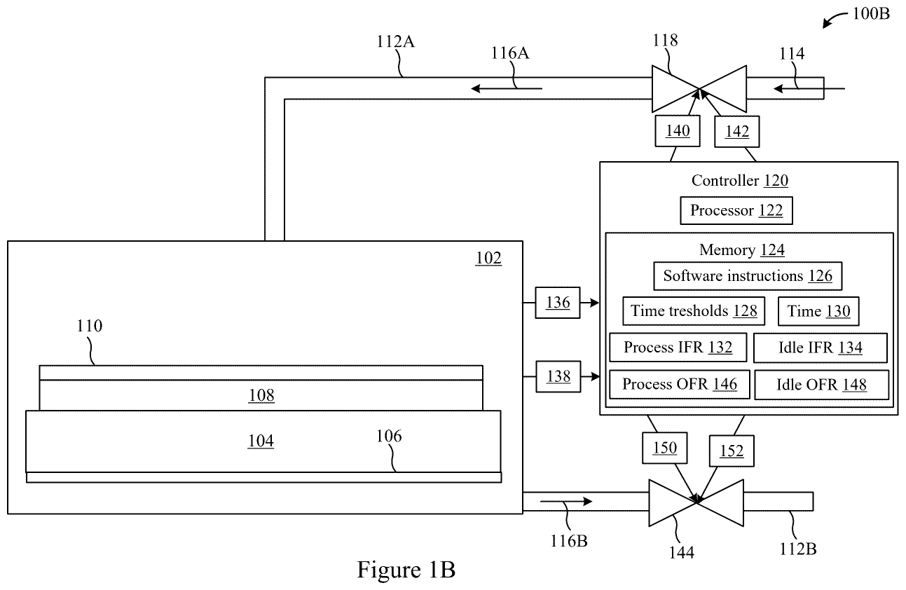

FIG. 1A is a schematic view of a baking apparatus 100A in accordance with various embodiments. The baking apparatus 100A is configured to perform a baking process on one or more wafers (e.g., wafer 110). In some embodiments, the baking apparatus 100A comprises a process chamber 102. A hot plate 108 is placed in the process chamber 102. The hot plate 108 may include one or more heating elements (not shown). In some embodiments, the one or more heating elements may comprise resistive heating elements, or the like. The hot plate 108 may be supported by a support platform 104. The support platform 104 may comprise various electrical and mechanical components (not shown) that are needed for operating the baking apparatus 100A. A back plate 106 is attached to the support platform 104 such that the support platform 104 is interposed between the back plate 106 and the hot plate 108.

The baking apparatus 100A may further comprise a plurality of conduits (e.g., conduits 112A and 112B). The plurality of conduits (e.g., conduits 112A and 112B) may comprise pipes that are configured to transfer gases in and out of the process chamber 102 of the baking apparatus 100A. The conduit 112A may be configured to accept a supply gas 114. In some embodiments, the supply gas 114 may comprise humid air. The humid air may have a temperature in a range from 20° C. to 30° C. and a humidity in a range from 40% to 50%. In some embodiments, a flow rate of the supply gas 114 is in a range from 1 liter per minute (L/min) to 8 L/min. In one embodiment, the flow rate of the supply gas 114 is 4 L/min. In some embodiments, the supply gas 114 may be provided to the process chamber 102 by a track temperature and humidity controller (not shown). In other embodiments, the supply gas 114 may be air that is pulled from around the process chamber 102. In yet other embodiments, the supply gas 114 may be clean dry air or N₂ gas supplied by the manufacturing facility.

In some embodiments, a valve 118 may be coupled to the conduit 112A. The valve 118 may be configured to control a flow of a gas through the conduit 112A. The valve 118 may comprise a check valve, a flow control valve, or any suitable valve. The valve 118 may be an electronically controlled valve that may be opened or closed in response to receiving signals from a controller 120. The valve 118 is configured to provide an incoming gas 116A into the process chamber 102 and change a flow rate of the incoming gas 116A. In some embodiments, the incoming gas 116A may comprise at least a portion of the supply gas 114. In some embodiments, the valve 118 may be a two-stage valve that may be switched between high and low flow rate modes. During the HFR mode, the valve 118 is configured to set the flow rate of the incoming gas 116A to a process incoming flow rate (IFR). In some embodiments, the process IFR may be in a range from 2 L/min to 8 L/min. In one embodiment, the process IFR is 4 L/min. During the LFR mode, the valve 118 is configured to set the flow rate of the incoming gas 116A to an idle IFR. In some embodiments, the idle IFR is less than the process IFR. In some embodiments, the idle IFR may be in a range from 0.25 L/min to 2 L/min. In one embodiment, the idle IFR is 1 L/min.

The conduit 112B may be configured to accept an outgoing gas 116B from the process chamber 102. The outgoing gas 116B may comprise a mixture of the incoming gas 116A and a process byproduct gas generated by the baking process. The process byproduct gas comprises process byproduct chemical generated by the baking process. In some embodiments, the conduit 112B is coupled to an exhaust of a fabrication facility to allow the outgoing gas 116B to be transferred to the exhaust. In some embodiments, a flow rate of the outgoing gas 116B equals to the process IFR during the HFR mode and the idle IFR during the LFR mode. By setting the flow rate of the outgoing gas 116B to the idle IFR during the LFR mode, an electrical power consumed by the hot plate 108 of the baking apparatus 100A is reduced.

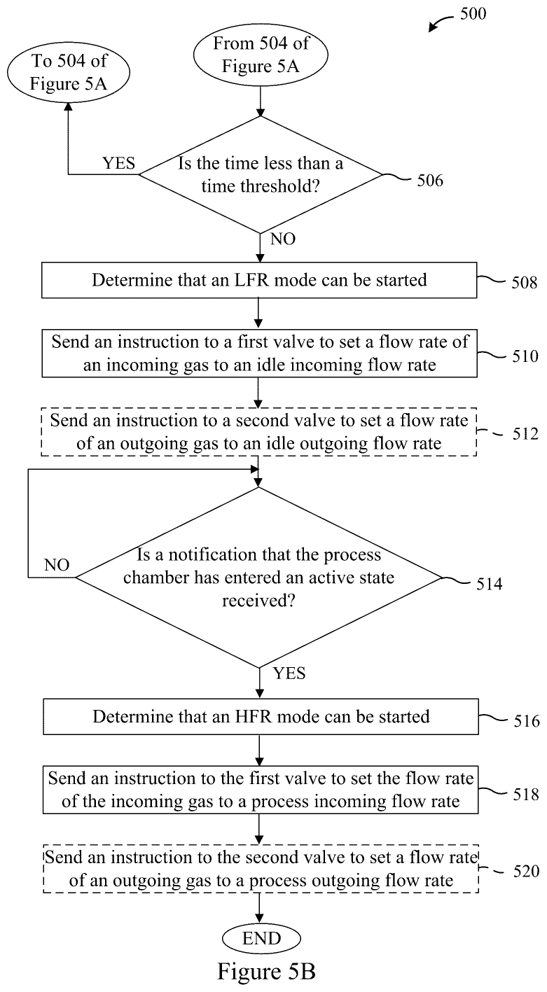

In some embodiments, the baking apparatus 100A further comprises the controller 120. The controller 120 is configured to send and/or receive signals to and/or from various components of the baking apparatus 100A to control the operation the baking apparatus 100A. The controller 120 may comprise a processor 122 communicatively coupled to a memory 124. The processor 122 may comprise one or more microprocessors. The memory 124 may comprise a non-transitory computer-readable medium that is configured to store software instructions 126 and/or any other data. The software instructions 126, when executed by the processor 122, cause the processor 122 to perform various functions of the controller 120 described herein. In some embodiments, the processor 122 of the controller 120 may generate instructions 140 and 142 that are transmitted to the valve 118. The instruction 140 may instruct the valve 118 to set the flow rate of the incoming gas 116A to the idle IFR. The instruction 142 may instruct the valve 118 to set the flow rate of the incoming gas 116A to the process IFR. The processor 122 of the controller 120 may be further configured to receive notifications 136 and 138 from the process chamber 102 of the baking apparatus 100A. In some embodiments, the baking apparatus 100A may be operated according to a method 500 described below with reference to FIGS. 5A and 5B.

FIG. 1B is a schematic view of a baking apparatus 100B in accordance with various embodiments. The baking apparatus 100B is configured to perform a baking process on one or more wafers (e.g., wafer 110). The baking apparatus 100B is similar to the baking apparatus 100A (see FIG. 1A), with similar features being labeled by similar numerical references, and descriptions of the similar features are not repeated herein. In the illustrated embodiments, the baking apparatus 100B comprises a valve 144 coupled to the conduit 112B. The valve 144 may be configured to control a flow of a gas through the conduit 112A. The valve 144 may comprise a check valve, a flow control valve, or any suitable valve. The valve 144 may be an electronically controlled valve that may be opened or closed in response to receiving signals from the controller 120. In some embodiments, the valve 144 may be a two-stage valve that may be switched between high and low flow rate modes. During the HFR mode, the valve 144 is configured to set the flow rate of the outgoing gas 116B to a process outgoing flow rate (OFR). In some embodiments, the process OFR may be in a range from 2 L/min to 8 L/min. In one embodiment, the process OFR is 4 L/min. During the LFR mode, the valve 144 is configured to set the flow rate of the outgoing gas 116B to an idle OFR. In some embodiments, the idle OFR is less than the process OFR. In some embodiments, the idle OFR may be in a range from 0.25 L/min to 2 L/min. In one embodiment, the idle OFR is 1 L/min.

In some embodiments, the processor 122 of the controller 120 may generate instructions 150 and 152 that are transmitted to the valve 144. The instruction 150 may instruct the valve 144 to set the flow rate of the outgoing gas 116B to the idle OFR. The instruction 152 may instruct the valve 144 to set the flow rate of the outgoing gas 116B to the process OFR. By setting the flow rate of the outgoing gas 116B to the idle OFR during the LFR mode, an electrical power consumed by the hot plate 108 of the baking apparatus 100B is reduced. In some embodiments, the baking apparatus 100B may be operated according to the method 500 described below with reference to FIGS. 5A and 5B.

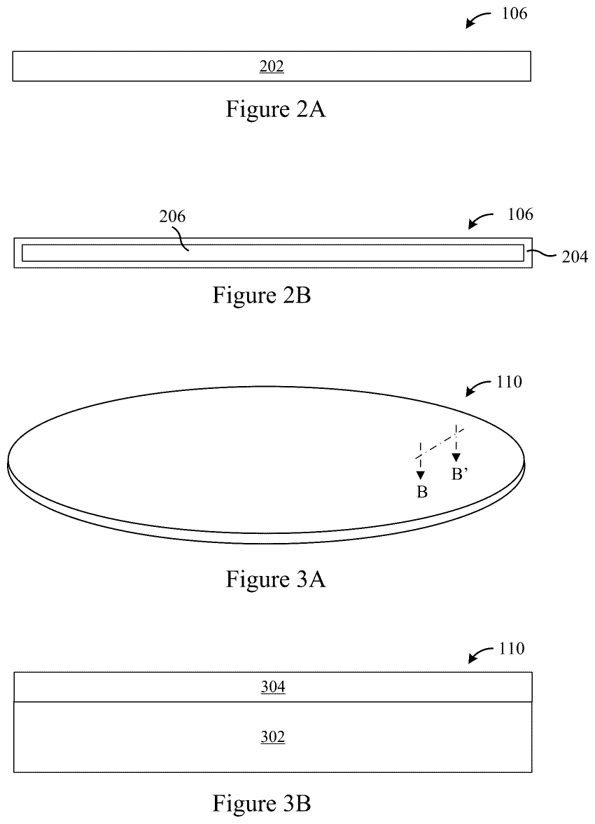

FIG. 2A illustrates a cross-sectional view of the back plate 106 (see FIGS. 1A and 1B) in accordance with various embodiments. In the illustrated embodiment, the back plate 106 comprises a solid sheet 202 of stainless steel. FIG. 2B illustrates a cross-sectional view of the back plate 106 (see FIGS. 1A and 1B) in accordance with various embodiments. In the illustrated embodiment, the back plate 106 comprises a sheet 204 of stainless steel. The sheet 204 may comprise a void 206 under a vacuum condition. By forming the void 206 under the vacuum condition within the sheet 204, the back plate 106 may be configured to reduce heat dissipation from the hot plate 108 (see FIGS. 1A and 1B) into the external environment. Accordingly, electrical power that otherwise would be consumed to compensate for the dissipated heat may be saved.

FIGS. 3A and 3B illustrate perspective and cross-sectionals view of the wafer 110 (see FIGS. 1A and 1B) in accordance with various embodiments. In particular, FIG. 3A illustrates a perspective view and FIG. 3B illustrates a cross-sectional view along a line BB′ shown in FIG. 3A. Referring to FIGS. 3A and 3B, the wafer 110 may comprise a substrate 302. The substrate 302 may include semiconductor devices or semiconductor structures and may be formed in any suitable manner, including using any suitable combination of wet and/or dry deposition and etch techniques. In such embodiments, the substrate 302 may include isolation regions such as shallow trench isolation (STI) regions, diffusion regions, as well as other regions formed therein.

The substrate 302 may comprise layers of semiconductors suitable for various microelectronics. In one or more embodiments, the substrate 302 may be a silicon wafer, or a silicon-on-insulator (SOI) wafer. In certain embodiments, the substrate 302 may comprise a silicon germanium wafer, silicon carbide wafer, gallium arsenide wafer, gallium nitride wafer, or other compound semiconductors. In other embodiments, the substrate 302 may comprise heterogeneous layers such as silicon germanium on silicon, gallium nitride on silicon, silicon carbon on silicon, or layers of silicon on a silicon or SOI substrate.

In some embodiments, a photoresist layer 304 may be formed over the substrate 302 using a suitable deposition process, such as spin-on deposition, chemical vapor deposition (CVD), or the like. The photoresist layer 304 may be patterned using suitable photolithography processes including an exposure to actinic radiation followed by a developing process. In some embodiments, the wafer 110 may be transferred into the process chamber 102 of the baking apparatus 100A or 100B (see FIGS. 1A and 1B) after depositing the photoresist layer 304 to perform a post-deposition baking process. In other embodiments, the wafer 110 may be transferred into the process chamber 102 of the baking apparatus 100A or 100B (see FIGS. 1A and 1B) after exposing the photoresist layer 304 to actinic radiation and before performing the developing process to perform a post-exposure baking process. In yet other embodiments, the wafer 110 may be transferred into the process chamber 102 of the baking apparatus 100A or 100B (see FIGS. 1A and 1B) after performing the developing process on the photoresist layer 304 to perform a post-developing baking process. The post-developing baking process may be also referred to as a hard baking process.

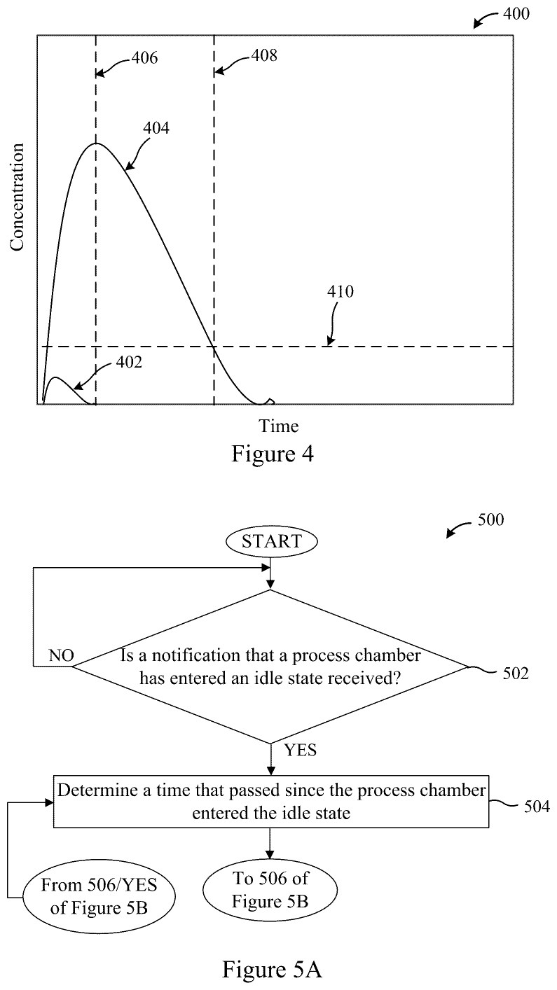

FIG. 4 illustrates a diagram 400 showing a dependence of a concentration of process byproduct chemicals in an outgoing gas (e.g., outgoing gas 116B of FIG. 1) time while performing, and possibly after performing, a baking process in accordance with various embodiments. A curve 402 shows a dependence of a concentration of process byproduct chemicals while performing a baking process on a first photoresist material. A curve 404 shows a dependence of a concentration of process byproduct chemicals while performing a baking process on a second photoresist material different from the first photoresist material.

The curves 402 and 404 may be used to determine HFR mode durations for the first photoresist material and the second photoresist material, respectively. After operating a baking apparatus (e.g., baking apparatus 100) in the HFR mode for the determined HFR mode duration, the baking apparatus is operated in the LFR mode. In some embodiments, the baking process may be performed for a process duration (identified by a dashed line 406) for both the first photoresist material and the second photoresist material. As shown by the curve 402, after performing the baking process, the process byproduct chemicals are substantially absent in the outgoing gas. In such embodiments, the process duration (identified by the dashed line 406) may be set as the HFR mode duration for the first photoresist material.

As shown by the curve 404, after performing the baking process, a substantial amount of the process byproduct chemicals is present in the outgoing gas. In such embodiments, a baking apparatus (e.g., baking apparatus 100) is operated in the HFR mode for the HFR mode duration (identified by a dashed line 408) that is greater than the process duration (identified by the dashed line 406) until the concentration of process byproduct chemicals is less than a threshold concentration (identified by a dashed line 410). The threshold concentration (identified by a dashed line 410) of process byproduct chemicals may be chosen such that after operating the baking apparatus in the HFR mode the process byproduct chemicals are substantially absent in the outgoing gas or are present in an amount that allows for a low defectivity level.

FIGS. 5A and 5B illustrate a flow diagram of a method 500 for reducing electrical consumption of a hot plate in accordance with various embodiments. The method 500 is described in conjunction with FIGS. 1A and 1B. The method 500 may be implemented, at least in part, in the form of executable code (e.g., software instructions 126 of FIG. 1A or 1B) stored on non-transitory, tangible, computer-readable medium (e.g., memory 124 of FIG. 1A or 1B) that when executed by one or more processors (e.g., processor 122 of FIG. 1A or 1B) may cause the one or more processors to perform one or more of the operations 502-520.

Method 500 starts with operation 502. In operation 502, a processor (e.g., processor 122 of FIG. 1A or 1B) of a controller (e.g., controller 120 of FIG. 1A or 1B) determines whether a notification (e.g., notification 136 of FIG. 1A or 1B) that a process chamber (e.g., process chamber 102 of FIG. 1A or 1B) has entered an idle state is received. In some embodiments, the processor (e.g., processor 122 of FIG. 1A or 1B) of the controller (e.g., controller 120 of FIG. 1A or 1B) may receive the notification (e.g., notification 136 of FIG. 1A or 1B) from the process chamber (e.g., process chamber 102 of FIG. 1A or 1B) of the baking apparatus (e.g., baking apparatus 100A or 100B of FIG. 1A or 1B, respectively). In some embodiments, operation 502 may be repeated one or more times until the notification (e.g., notification 136 of FIG. 1A or 1B) that the process chamber (e.g., process chamber 102 of FIG. 1A or 1B) has entered the idle state is received. The baking apparatus (e.g., baking apparatus 100A or 100B of FIG. 1A or 1B, respectively) may process one or more wafers before the notification (e.g., notification 136 of FIG. 1A or 1B) that the process chamber (e.g., process chamber 102 of FIG. 1A or 1B) has entered the idle state is received. In some embodiments when the baking apparatus (e.g., baking apparatus 100A or 100B of FIG. 1A or 1B, respectively) processes multiple wafers, the multiple wafers may belong to a same batch or different batches.

In response to determining at operation 502 that the notification (e.g., notification 136 of FIG. 1A or 1B) that the process chamber (e.g., process chamber 102 of FIG. 1A or 1B) has entered the idle state is received, method 500 proceeds to operation 504. In operation 504, the processor (e.g., processor 122 of FIG. 1A or 1B) of the controller (e.g., controller 120 of FIG. 1A or 1B) determines a time (e.g., time 130 of FIG. 1A or 1B) that passed since process chamber (e.g., process chamber 102 of FIG. 1A or 1B) entered the idle state.

In operation 506, the processor (e.g., processor 122 of FIG. 1A or 1B) of the controller (e.g., controller 120 of FIG. 1A or 1B) determines whether the time (e.g., time 130 of FIG. 1A or 1B) is less than a time threshold (e.g., time threshold 128 of FIG. 1A or 1B). In response to determining at operation 506 that the time (e.g., time 130 of FIG. 1A or 1B) is less than the time threshold (e.g., time threshold 128 of FIG. 1A or 1B), method 500 proceeds to operation 504. In some embodiments, operations 504 and 506 may be performed one or more times until the time (e.g., time 130 of FIG. 1A or 1B) is equal to the time threshold (e.g., time threshold 128 of FIG. 1A or 1B).

In response to determining at operation 506 that the time (e.g., time 130 of FIG. 1A or 1B) is equal to the time threshold (e.g., time threshold 128 of FIG. 1A or 1B), method 500 proceeds to operation 508. In operation 508, the processor (e.g., processor 122 of FIG. 1A or 1B) of the controller (e.g., controller 120 of FIG. 1A or 1B) determines that an LFR mode can be started. In operation 510, the processor (e.g., processor 122 of FIG. 1A or 1B) of the controller (e.g., controller 120 of FIG. 1A or 1B) sends an instruction (e.g., instruction 140 of FIG. 1A or 1B) to a first valve (e.g., valve 118 of FIG. 1A or 1B) to set a flow rate of an incoming gas (e.g., incoming gas 116A of FIG. 1A or 1B) to an idle IFR (e.g., idle IFR 134 of FIG. 1A or 1B).

In some embodiments when method 500 is performed by the baking apparatus 100A of FIG. 1A, method 500 proceeds to operation 514 after performing operation 510. In some embodiments when method 500 is performed by the baking apparatus 100B of FIG. 1B, method 500 proceeds to operation 512 after performing operation 510. In operation 512, the processor (e.g., processor 122 of FIG. 1B) of the controller (e.g., controller 120 of FIG. 1B) sends an instruction (e.g., instruction 150 of FIG. 1B) to a second valve (e.g., valve 144 of FIG. 1B) to set a flow rate of an outgoing gas (e.g., outgoing gas 116B of FIG. 1B) to an idle OFR (e.g., idle OFR 148 of FIG. 1B).

In operation 514, the processor (e.g., processor 122 of FIG. 1A or 1B) of the controller (e.g., controller 120 of FIG. 1A or 1B) determines whether a notification (e.g., notification 138 of FIG. 1A or 1B) that the baking apparatus (e.g., baking apparatus 100A or 100B of FIG. 1A or 1B, respectively) has entered an active state is received. In some embodiments, the processor (e.g., processor 122 of FIG. 1A or 1B) of the controller (e.g., controller 120 of FIG. 1A or 1B) may receive the notification (e.g., notification 138 of FIG. 1A or 1B) from the process chamber (e.g., process chamber 102 of FIG. 1A or 1B) of the baking apparatus (e.g., baking apparatus 100A or 100B of FIG. 1A or 1B, respectively). In some embodiments, operation 514 may be repeated one or more times until the notification (e.g., notification 138 of FIG. 1A or 1B) that the baking apparatus (e.g., baking apparatus 100A or 100B of FIG. 1A or 1B, respectively) has entered the active state is received.

In response to determining at operation 514 that the notification (e.g., notification 138 of FIG. 1A or 1B) that the baking apparatus (e.g., baking apparatus 100A or 100B of FIG. 1A or 1B, respectively) has entered the active state is received, method 500 proceeds to operation 516. In operation 516, the processor (e.g., processor 122 of FIG. 1A or 1B) of the controller (e.g., controller 120 of FIG. 1A or 1B) determines that an HFR mode can be started. In operation 518, the processor (e.g., processor 122 of FIG. 1A or 1B) of the controller (e.g., controller 120 of FIG. 1A or 1B) sends an instruction (e.g., instruction 142 of FIG. 1A or 1B) to the first valve (e.g., valve 118 of FIG. 1A or 1B) to set the flow rate of the incoming gas (e.g., incoming gas 116A of FIG. 1A or 1B) to a process IFR (e.g., process IFR 132 of FIG. 1A or 1B).

In some embodiments when method 500 is performed by the baking apparatus 100A of FIG. 1A, method 500 proceeds to end after performing operation 518. In some embodiments when method 500 is performed by the baking apparatus 100B of FIG. 1B, method 500 proceeds to operation 520 after performing operation 518. In operation 520, the processor (e.g., processor 122 of FIG. 1B) of the controller (e.g., controller 120 of FIG. 1B) sends an instruction (e.g., instruction 152 of FIG. 1B) to the second valve (e.g., valve 144 of FIG. 1B) to set the flow rate of the outgoing gas (e.g., outgoing gas 116B of FIG. 1B) to a process OFR (e.g., process OFR 146 of FIG. 1B). In some embodiments, after performing operation 518 or 520, method 500 proceeds to end. In other embodiments, after performing operation 518 or 520, method 500 proceeds to operation 502. In such embodiments, operations 502-520 of method 500 may be performed in a loop.

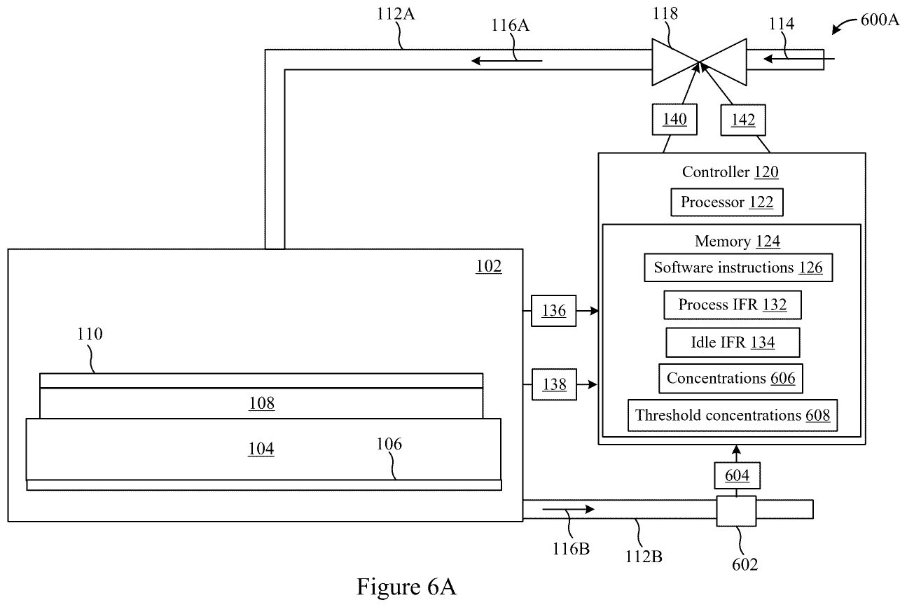

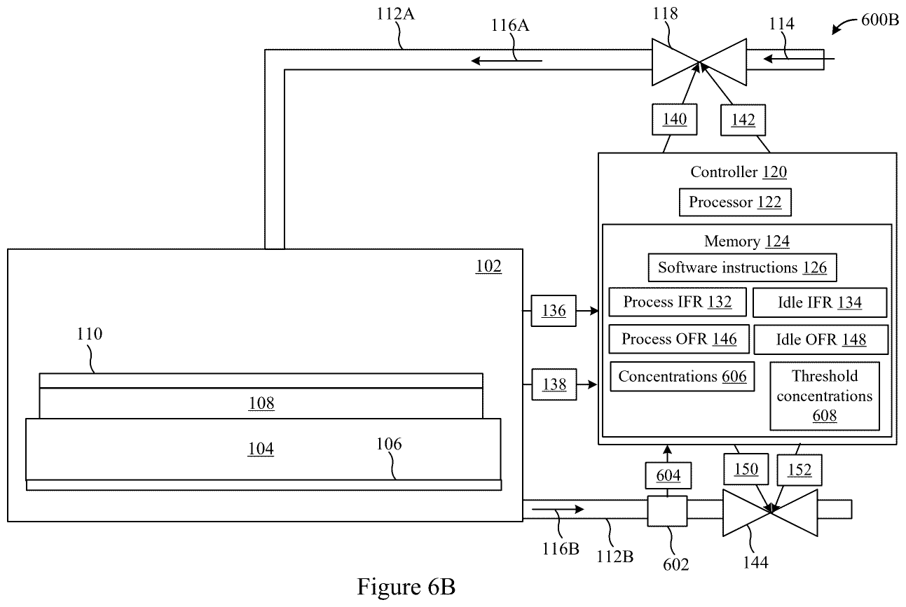

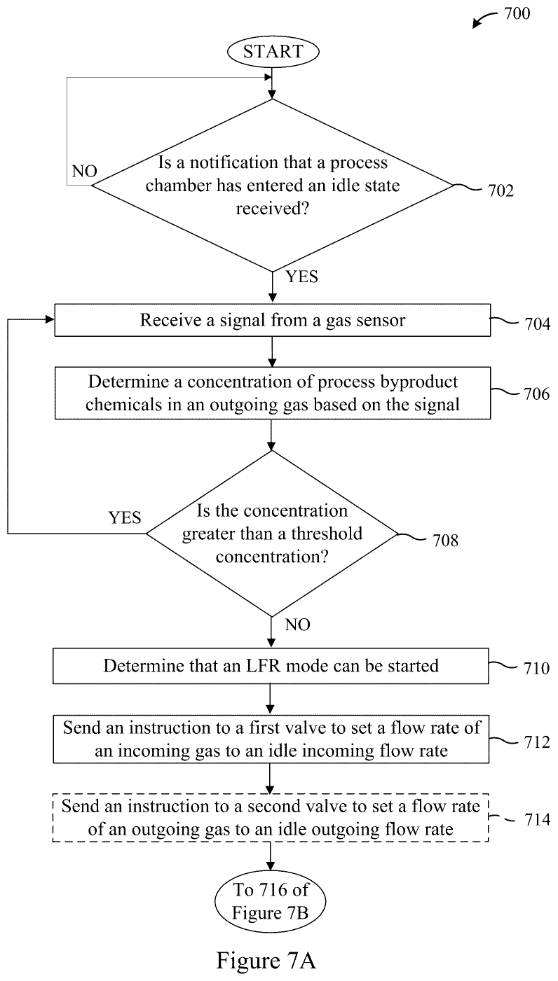

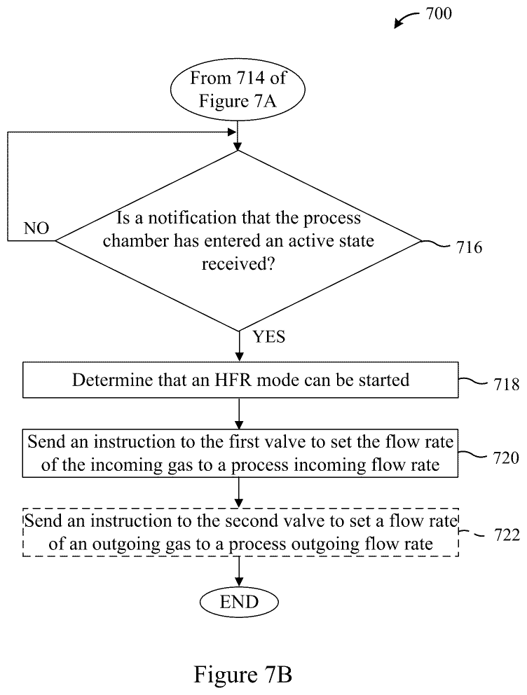

FIG. 6A is a schematic view of a baking apparatus 600A in accordance with various embodiments. The baking apparatus 600A is configured to perform a baking process on one or more wafers (e.g., wafer 110). The baking apparatus 600A is similar to the baking apparatus 100A (see FIG. 1A), with similar features being labeled by similar numerical references, and descriptions of the similar features are not repeated herein. In the illustrated embodiments, the baking apparatus 600A comprises a gas sensor 602 coupled to the conduit 112B. In some embodiments, the gas sensor 602 may be a micro-electromechanical system (MEMS) gas sensor. The gas sensor 602 is configured to send a signal 604 to the controller 120 based on a sensed concentration of process byproduct chemicals in the outgoing gas 116B. In some embodiments, the curves 402 and 404 (see FIG. 4) may be determined using the gas sensor 602. In some embodiments, the baking apparatus 600A may be operated according to a method 700 described below with reference to FIGS. 7A and 7B.

FIG. 6B is a schematic view of a baking apparatus 600B in accordance with various embodiments. The baking apparatus 600B is configured to perform a baking process on one or more wafers (e.g., wafer 110). The baking apparatus 600B is similar to the baking apparatus 100B (see FIG. 1B), with similar features being labeled by similar numerical references, and descriptions of the similar features are not repeated herein. In the illustrated embodiments, the baking apparatus 600B comprises a gas sensor 602 coupled to the conduit 112B. In some embodiments, the gas sensor 602 may be a micro-electromechanical system (MEMS) gas sensor. The gas sensor 602 is configured to send a signal 604 to the controller 120 based on a sensed concentration of process byproduct chemicals in the outgoing gas 116B. In some embodiments, the curves 402 and 404 (see FIG. 4) may be determined using the gas sensor 602. In some embodiments, the baking apparatus 600B may be operated according to a method 700 described below with reference to FIGS. 7A and 7B.

FIGS. 7A and 7B illustrate a flow diagram of a method 700 for reducing electrical consumption of a hot plate in accordance with various embodiments. The method 700 is described in conjunction with FIGS. 6A and 6B. The method 700 may be implemented, at least in part, in the form of executable code (e.g., software instructions 126 of FIG. 6A or 6B) stored on non-transitory, tangible, computer-readable medium (e.g., memory 124 of FIG. 6A or 6B) that when executed by one or more processors (e.g., processor 122 of FIG. 6A or 6B) may cause the one or more processors to perform one or more of the operations 702-722.

Method 700 starts with operation 702. In operation 702, a processor (e.g., processor 122 of FIG. 6A or 6B) of a controller (e.g., controller 120 of FIG. 6A or 6B) determines whether a notification (e.g., notification 136 of FIG. 6A or 6B) that a process chamber (e.g., process chamber 102 of FIG. 6A or 6B) has entered an idle state is received. In some embodiments, the processor (e.g., processor 122 of FIG. 6A or 6B) of the controller (e.g., controller 120 of FIG. 6A or 6B) may receive the notification (e.g., notification 136 of FIG. 6A or 6B) from the process chamber (e.g., process chamber 102 of FIG. 6A or 6B) of the baking apparatus (e.g., baking apparatus 600A or 600B of FIG. 6A or 6B, respectively). In some embodiments, operation 702 may be repeated one or more times until the notification (e.g., notification 136 of FIG. 6A or 6B) that the process chamber (e.g., process chamber 102 of FIG. 6A or 6B) has entered the idle state is received. The baking apparatus (e.g., baking apparatus 600A or 600B of FIG. 6A or 6B, respectively) may process one or more wafers before the notification (e.g., notification 136 of FIG. 6A or 6B) that the process chamber (e.g., process chamber 102 of FIG. 6A or 6B) has entered the idle state is received. In some embodiments when the baking apparatus (e.g., baking apparatus 600A or 600B of FIG. 6A or 6B, respectively) processes multiple wafers, the multiple wafers may belong to a same batch or different batches.

In response to determining at operation 702 that the notification (e.g., notification 136 of FIG. 6A or 6B) that the process chamber (e.g., process chamber 102 of FIG. 6A or 6B) has entered the idle state is received, method 700 proceeds to operation 704. In operation 704, the processor (e.g., processor 122 of FIG. 6A or 6B) of the controller (e.g., controller 120 of FIG. 6A or 6B) receives a signal (e.g., signal 604 of FIG. 6A or 6B) from a gas sensor (e.g., gas sensor 602 of FIG. 6A or 6B). In operation 706, the processor (e.g., processor 122 of FIG. 6A or 6B) of the controller (e.g., controller 120 of FIG. 6A or 6B) determines a concentration (e.g., concentration 606 of FIG. 6A or 6B) of process byproduct chemicals in an outgoing gas (e.g., outgoing gas 116B of FIG. 6A or 6B) based on the signal (e.g., signal 604 of FIG. 6A or 6B).

In operation 708, the processor (e.g., processor 122 of FIG. 6A or 6B) of the controller (e.g., controller 120 of FIG. 6A or 6B) determines whether the concentration (e.g., concentration 606 of FIG. 6A or 6B) is greater than a threshold concentration (e.g., threshold concentration 608 of FIG. 6A or 6B). In response to determining at operation 708 that the concentration (e.g., concentration 606 of FIG. 6A or 6B) is greater than the threshold concentration (e.g., threshold concentration 608 of FIG. 6A or 6B), method 700 proceeds to operation 704. In some embodiments, operations 704-708 may be repeated one or more times until the concentration (e.g., concentration 606 of FIG. 6A or 6B) is less than or equal to the threshold concentration (e.g., threshold concentration 608 of FIG. 6A or 6B).

In response to determining at operation 708 that the concentration (e.g., concentration 606 of FIG. 6A or 6B) is less than or equal to the threshold concentration (e.g., threshold concentration 608 of FIG. 6A or 6B), method 700 proceeds to operation 710. In operation 710, the processor (e.g., processor 122 of FIG. 6A or 6B) of the controller (e.g., controller 120 of FIG. 6A or 6B) determines that an LFR mode can be started. In operation 712, the processor (e.g., processor 122 of FIG. 6A or 6B) of the controller (e.g., controller 120 of FIG. 6A or 6B) sends an instruction (e.g., instruction 140 of FIG. 6A or 6B) to a first valve (e.g., valve 118 of FIG. 6A or 6B) to set a flow rate of an incoming gas (e.g., incoming gas 116A of FIG. 6A or 6B) to an idle IFR (e.g., idle IFR 134 of FIG. 6A or 6B).

In some embodiments when method 700 is performed by the baking apparatus 600A of FIG. 6A, method 700 proceeds to operation 716 after performing operation 712. In some embodiments when method 700 is performed by the baking apparatus 600B of FIG. 6B, method 700 proceeds to operation 714 after performing operation 712. In operation 714, the processor (e.g., processor 122 of FIG. 6B) of the controller (e.g., controller 120 of FIG. 6B) sends an instruction (e.g., instruction 150 of FIG. 6B) to a second valve (e.g., valve 144 of FIG. 6B) to set a flow rate of an outgoing gas (e.g., outgoing gas 116B of FIG. 6B) to an idle OFR (e.g., idle OFR 148 of FIG. 6B).

In operation 716, the processor (e.g., processor 122 of FIG. 6A or 6B) of the controller (e.g., controller 120 of FIG. 6A or 6B) determines whether a notification (e.g., notification 138 of FIG. 6A or 6B) that the baking apparatus (e.g., baking apparatus 600A or 600B of FIG. 6A or 6B, respectively) has entered an active state is received. In some embodiments, the processor (e.g., processor 122 of FIG. 6A or 6B) of the controller (e.g., controller 120 of FIG. 6A or 6B) may receive the notification (e.g., notification 138 of FIG. 6A or 6B) from the process chamber (e.g., process chamber 102 of FIG. 6A or 6B) of the baking apparatus (e.g., baking apparatus 600A or 600B of FIG. 6A or 6B, respectively). In some embodiments, operation 716 may be repeated one or more times until the notification (e.g., notification 138 of FIG. 6A or 6B) that the baking apparatus (e.g., baking apparatus 600A or 600B of FIG. 6A or 6B, respectively) has entered the active state is received.

In response to determining at operation 716 that the notification (e.g., notification 138 of FIG. 6A or 6B) that the baking apparatus (e.g., baking apparatus 600A or 600B of FIG. 6A or 6B, respectively) has entered the active state is received, method 700 proceeds to operation 718. In operation 718, the processor (e.g., processor 122 of FIG. 6A or 6B) of the controller (e.g., controller 120 of FIG. 6A or 6B) determines that an HFR mode can be started. In operation 720, the processor (e.g., processor 122 of FIG. 6A or 6B) of the controller (e.g., controller 120 of FIG. 6A or 6B) sends an instruction (e.g., instruction 142 of FIG. 6A or 6B) to the first valve (e.g., valve 118 of FIG. 6A or 6B) to set the flow rate of the incoming gas (e.g., incoming gas 116A of FIG. 6A or 6B) to a process IFR (e.g., process IFR 132 of FIG. 6A or 6B).

In some embodiments when method 700 is performed by the baking apparatus 600A of FIG. 1A, method 700 proceeds to end after performing operation 720. In some embodiments when method 700 is performed by the baking apparatus 600B of FIG. 6B, method 700 proceeds to operation 722 after performing operation 720. In operation 722, the processor (e.g., processor 122 of FIG. 6B) of the controller (e.g., controller 120 of FIG. 6B) sends an instruction (e.g., instruction 152 of FIG. 6B) to the second valve (e.g., valve 144 of FIG. 6B) to set the flow rate of the outgoing gas (e.g., outgoing gas 116B of FIG. 6B) to a process OFR (e.g., process OFR 146 of FIG. 6B). In some embodiments, after performing operation 720 or 722, method 700 proceeds to end. In other embodiments, after performing operation 720 or 722, method 700 proceeds to operation 702. In such embodiments, operations 702-722 of method 700 may be performed in a loop.

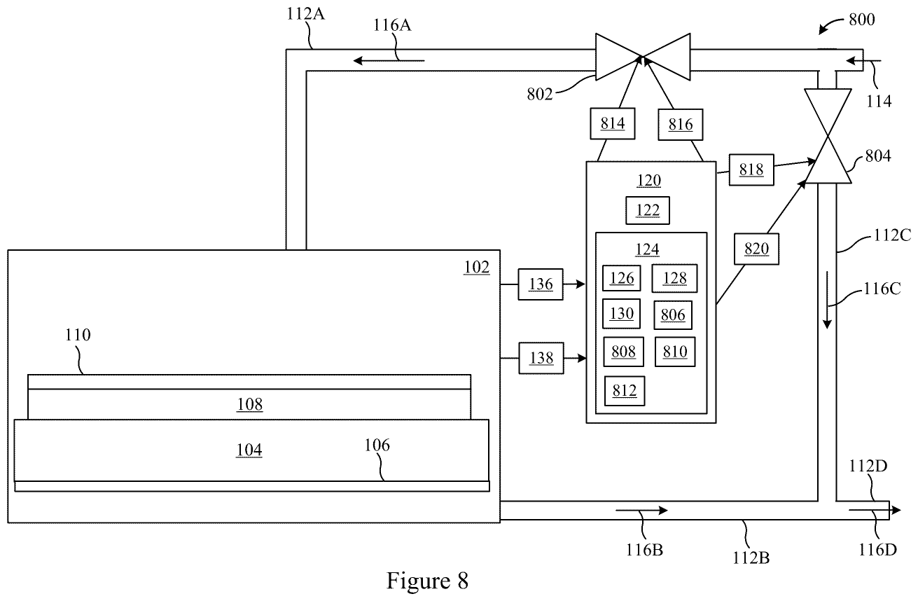

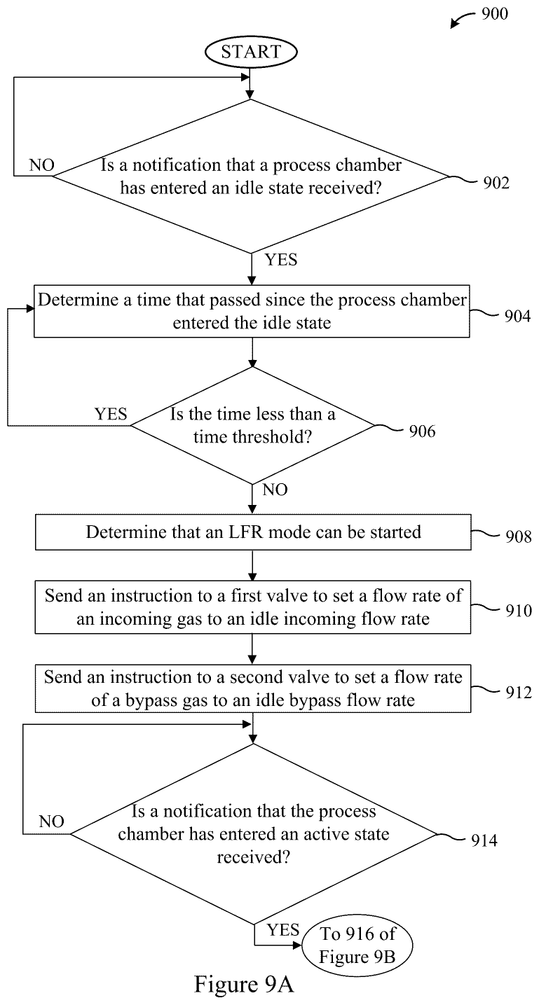

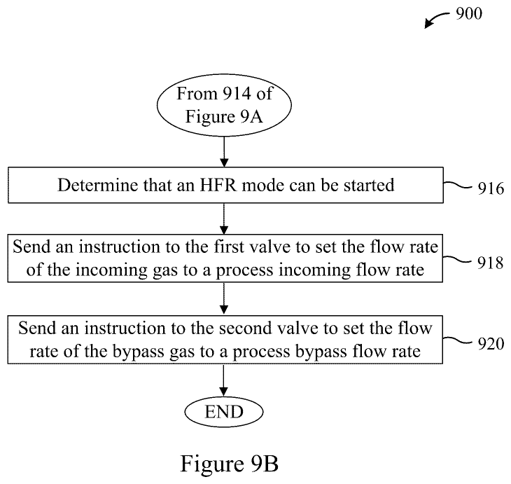

FIG. 8 is a schematic view of a baking apparatus 800 in accordance with various embodiments. The baking apparatus 800 is configured to perform a baking process on one or more wafers (e.g., wafer 110). In some embodiments, the baking apparatus 800 may be operated according to a method 900 described below with reference to FIGS. 9A and 9B. The baking apparatus 800 is similar to the baking apparatus 100A (see FIG. 1A), with similar features being labeled by similar numerical references, and descriptions of the similar features are not repeated herein. In the illustrated embodiments, the baking apparatus 800 comprises a conduit 112C that connects the conduit 112A and the conduit 112B, and a conduit 112D that is connected to the conduits 112B and 112C.

In some embodiments, valves 802 and 804 may be coupled to the conduits 112A and 112C, respectively. The valves 802 and 804 may be configured to control a flow of a gas through the conduits 112A and 112C, respectively. Each of the valves 802 and 804 may comprise a check valve, a flow control valve, or any suitable valve. The valves 802 and 804 may be electronically controlled valves that may be opened or closed in response to receiving signals from the controller 120. In some embodiments, the processor 122 of the controller 120 may generate instructions 814 and 816 that are transmitted to the valve 802 and instructions 818 and 820 that are transmitted to the valve 804. The valves 802 and 804 are configured to split the supply gas 114 into an incoming gas 116A and a bypass gas 116C. In some embodiments, the incoming gas 116A comprises at least a portion of the supply gas 114 and the bypass gas 116C comprises a remaining portion of the supply gas 114. The valve 802 is configured provide the incoming gas 116A into the process chamber 102 and change a flow rate of the incoming gas 116A. The valve 804 is configured provide the bypass gas 116C to the conduit 112D and change a flow rate of the bypass gas 116C.

The conduit 112D may be configured to accept the outgoing gas 116B from the conduit 112D and the bypass gas 116C from the conduit 112C. In some embodiments, a flow rate of the outgoing gas 116B equals to the flow rate of the incoming gas 116A. In some embodiments, the conduit 112D is coupled to an exhaust of a fabrication facility to allow a mixture of the outgoing gas 116B and the bypass gas 116C to be transferred to the exhaust. The mixture of the outgoing gas 116B and the bypass gas 116C may be also referred to as an exhaust gas 116D. In some embodiments, a flow rate of the exhaust gas 116D is a sum of the flow rate of the outgoing gas 116B and the flow rate of the bypass gas 116C. In some embodiments, the flow rate of the exhaust gas 116D is the same in both HFR and LFR modes.

During the HFR mode, the valve 802 is configured to set the flow rate of the incoming gas 116A to a process IFR and the valve 804 is configured to set the flow rate of the bypass gas 116C to a process bypass flow rate (BFR). In some embodiments, the process IFR may be in a range from 2 L/min to 8 L/min and the process BFR may be in a range from 0 L/min to 2 L/min. In an embodiment when the flow rate of the supply gas 114 is set to 4 L/min, the process IFR is set to 4 L/min and the process BFR is set 0 L/min. In such embodiment, the flow rate of the exhaust gas 116D equals 4 L/min.

During the LFR mode, the valve 802 is configured to set the flow rate of the incoming gas 116A to an idle incoming flow rate and the valve 804 is configured to set the flow rate of the bypass gas 116C to an idle bypass flow rate. In some embodiments, the idle incoming flow rate is less than the process incoming flow rate. In some embodiments, the idle bypass flow rate is greater than the process bypass flow rate. In some embodiments, a sum of the process incoming flow rate and the process bypass flow rate is equal to a sum of the idle incoming flow rate and the idle bypass flow rate. In some embodiments, the idle IFR may be in a range from 0.25 L/min to 2 L/min and the idle BFR may be in a range from 1.75 L/min to 7.75 L/min. In an embodiment when the flow rate of the supply gas 114 is set to 4 L/min, the idle IFR is set to 1 L/min and the idle BFR is set to 3 L/min. In such embodiment, the flow rate of the exhaust gas 116D equals 4 L/min.

FIGS. 9A and 9B illustrate a flow diagram of a method 900 for reducing electrical consumption of a hot plate in accordance with various embodiments. The method 900 is described in conjunction with FIG. 8. The method 900 may be implemented, at least in part, in the form of executable code (e.g., software instructions 126 of FIG. 8) stored on non-transitory, tangible, computer-readable medium (e.g., memory 124 of FIG. 8) that when executed by one or more processors (e.g., processor 122 of FIG. 8) may cause the one or more processors to perform one or more of the operations 902-920.

Method 900 starts with operation 902. In operation 902, a processor (e.g., processor 122 of FIG. 8) of a controller (e.g., controller 120 of FIG. 8) determines whether a notification (e.g., notification 136 of FIG. 8) that a process chamber (e.g., process chamber 102 of FIG. 8) has entered an idle state is received. In some embodiments, the processor (e.g., processor 122 of FIG. 8) of the controller (e.g., controller 120 of FIG. 8) may receive the notification (e.g., notification 136 of FIG. 8) from the process chamber (e.g., process chamber 102 of FIG. 8) of the baking apparatus (e.g., baking apparatus 800 of FIG. 8). In some embodiments, operation 902 may be repeated one or more times until the notification (e.g., notification 136 of FIG. 8) that the process chamber (e.g., process chamber 102 of FIG. 8) has entered the idle state is received. The baking apparatus (e.g., baking apparatus 800 of FIG. 8) may process one or more wafers before the notification (e.g., notification 136 of FIG. 8) that the process chamber (e.g., process chamber 102 of FIG. 8) has entered the idle state is received. In some embodiments when the baking apparatus (e.g., baking apparatus 800 of FIG. 8) processes multiple wafers, the multiple wafers may belong to a same batch or different batches.

In response to determining at operation 902 that the notification (e.g., notification 136 of FIG. 8) that the process chamber (e.g., process chamber 102 of FIG. 8) has entered the idle state is received, method 900 proceeds to operation 904. In operation 904, the processor (e.g., processor 122 of FIG. 8) of the controller (e.g., controller 120 of FIG. 8) determines a time (e.g., time 130 of FIG. 8) that passed since the process chamber (e.g., process chamber 102 of FIG. 8) entered the idle state.

In operation 906, the processor (e.g., processor 122 of FIG. 8) of the controller (e.g., controller 120 of FIG. 8) determines whether the time (e.g., time 130 of FIG. 8) is less than a time threshold (e.g., time threshold 128 of FIG. 8). In response to determining at operation 906 that the time (e.g., time 130 of FIG. 8) is less than the time threshold (e.g., time threshold 128 of FIG. 8), method 900 proceeds to operation 904. In some embodiments, operations 904 and 906 may be performed one or more times until the time (e.g., time 130 of FIG. 8) is equal to the time threshold (e.g., time threshold 128 of FIG. 8).

In response to determining at operation 906 that the time (e.g., time 130 of FIG. 8) is equal to the time threshold (e.g., time threshold 128 of FIG. 8), method 900 proceeds to operation 908. In operation 908, the processor (e.g., processor 122 of FIG. 8) of the controller (e.g., controller 120 of FIG. 8) determines that an LFR mode can be started. In operation 910, the processor (e.g., processor 122 of FIG. 8) of the controller (e.g., controller 120 of FIG. 8) sends an instruction (e.g., instruction 814 of FIG. 8) to a first valve (e.g., valve 802 of FIG. 8) to set a flow rate of an incoming gas (e.g., incoming gas 116A of FIG. 8) to an idle IFR (e.g., idle IFR 806 of FIG. 8). In operation 912, the processor (e.g., processor 122 of FIG. 8) of the controller (e.g., controller 120 of FIG. 8) sends an instruction (e.g., instruction 818 of FIG. 8) to a second valve (e.g., valve 804 of FIG. 8) to set a flow rate of a bypass gas (e.g., bypass gas 116C of FIG. 8) to an idle BFR (e.g., idle BFR 808 of FIG. 8).

In operation 914, the processor (e.g., processor 122 of FIG. 8) of the controller (e.g., controller 120 of FIG. 8) determines whether a notification (e.g., notification 138 of FIG. 8) that the baking apparatus (e.g., baking apparatus 800 of FIG. 8) has entered an active state is received. In some embodiments, the processor (e.g., processor 122 of FIG. 8) of the controller (e.g., controller 120 of FIG. 8) may receive the notification (e.g., notification 138 of FIG. 8) from the process chamber (e.g., process chamber 102 of FIG. 8) of the baking apparatus (e.g., baking apparatus 800 of FIG. 8). In some embodiments, operation 914 may be repeated one or more times until the notification (e.g., notification 138 of FIG. 8) that the baking apparatus (e.g., baking apparatus 800 of FIG. 8) has entered the active state is received.

In response to determining at operation 914 that the notification (e.g., notification 138 of FIG. 8) that the baking apparatus (e.g., baking apparatus 800 of FIG. 8) has entered the active state is received, method 900 proceeds to operation 916. In operation 916, the processor (e.g., processor 122 of FIG. 8) of the controller (e.g., controller 120 of FIG. 8) determines that an HFR mode can be started. In operation 918, the processor (e.g., processor 122 of FIG. 8) of the controller (e.g., controller 120 of FIG. 8) sends an instruction (e.g., instruction 816 of FIG. 8) to the first valve (e.g., valve 802 of FIG. 8) to set the flow rate of the incoming gas (e.g., incoming gas 116A of FIG. 8) to a process IFR (e.g., process IFR 810 of FIG. 8). In operation 920, the processor (e.g., processor 122 of FIG. 8) of the controller (e.g., controller 120 of FIG. 8) sends an instruction (e.g., instruction 820 of FIG. 8) to the second valve (e.g., valve 804 of FIG. 8) to set the flow rate of the bypass gas (e.g., bypass gas 116C of FIG. 8) to a process BFR (e.g., process BFR 812 of FIG. 8). In some embodiments, after performing operation 920, method 900 proceeds to end. In other embodiments, after performing operation 920, method 900 proceeds to operation 902. In such embodiments, operations 902-920 of method 900 may be performed in a loop.

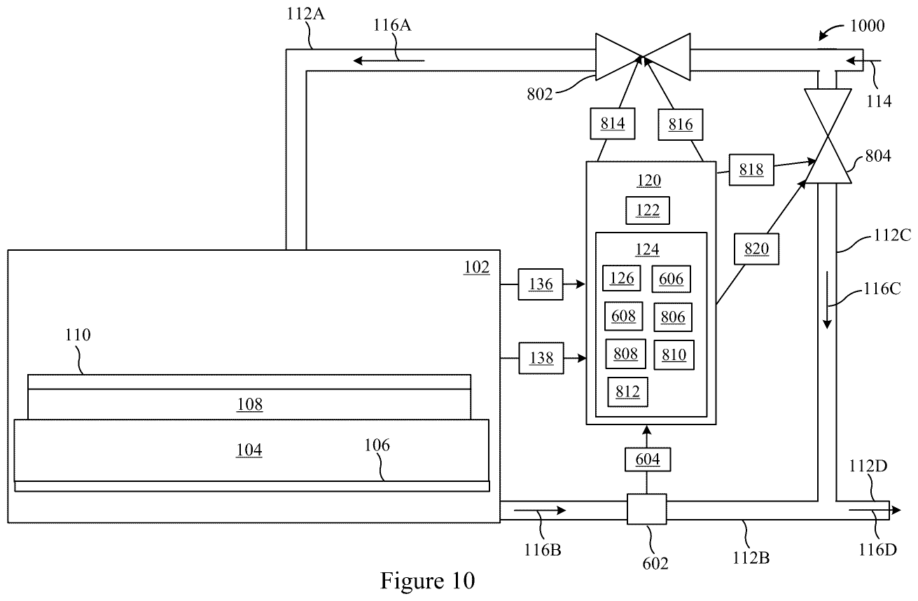

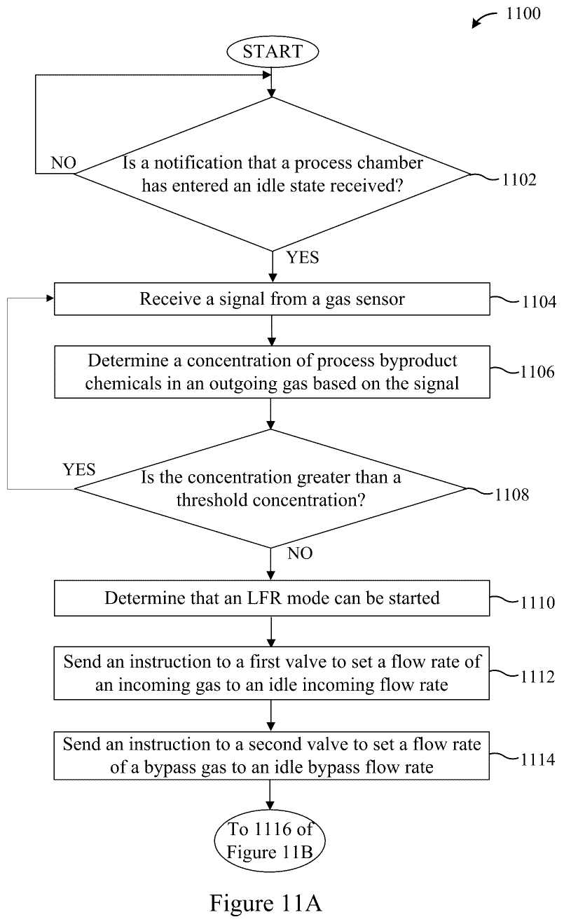

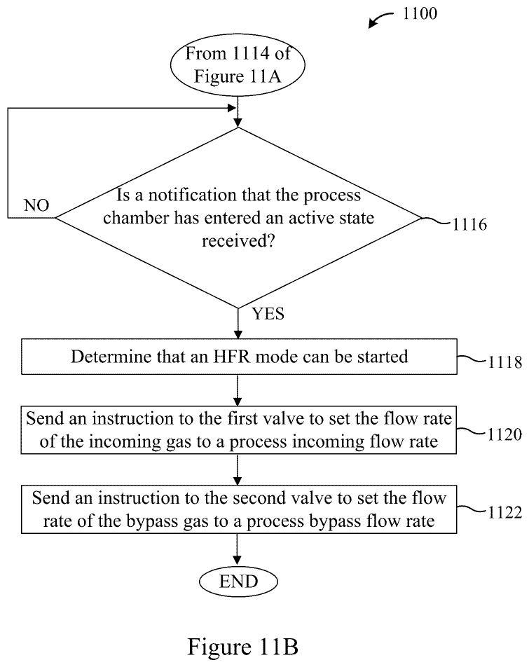

FIG. 10 is a schematic view of a baking apparatus 1000 in accordance with various embodiments. The baking apparatus 1000 is configured to perform a baking process on one or more wafers (e.g., wafer 110). The baking apparatus 1000 is similar to the baking apparatus 800 (see FIG. 8), with similar features being labeled by similar numerical references, and descriptions of the similar features are not repeated herein. In the illustrated embodiments, the baking apparatus 1000 comprises a gas sensor 602 coupled to the conduit 112B. In some embodiments, the gas sensor 602 may be a micro-electromechanical system (MEMS) gas sensor. The gas sensor 602 is configured to send a signal 604 to the controller 120 based on a sensed concentration of process byproduct chemicals in the outgoing gas 116B. In some embodiments, the baking apparatus 1000 may be operated according to a method 1100 described below with reference to FIGS. 11A and 11B.

FIGS. 11A and 11B illustrate a flow diagram of a method 1100 for reducing electrical consumption of a hot plate in accordance with various embodiments. The method 1100 is described in conjunction with FIG. 10. The method 1100 may be implemented, at least in part, in the form of executable code (e.g., software instructions 126 of FIG. 10) stored on non-transitory, tangible, computer-readable medium (e.g., memory 124 of FIG. 10) that when executed by one or more processors (e.g., processor 122 of FIG. 10) may cause the one or more processors to perform one or more of the operations 1102-1122.

Method 1100 starts with operation 1102. In operation 1102, a processor (e.g., processor 122 of FIG. 10) of a controller (e.g., controller 120 of FIG. 10) determines whether a notification (e.g., notification 136 of FIG. 10) that a process chamber (e.g., process chamber 102 of FIG. 10) has entered an idle state is received. In some embodiments, the processor (e.g., processor 122 of FIG. 10) of the controller (e.g., controller 120 of FIG. 10) may receive the notification (e.g., notification 136 of FIG. 10) from the process chamber (e.g., process chamber 102 of FIG. 10) of the baking apparatus (e.g., baking apparatus 1000 of FIG. 10). In some embodiments, operation 1102 may be repeated one or more times until the notification (e.g., notification 136 of FIG. 10) that the process chamber (e.g., process chamber 102 of FIG. 10) has entered the idle state is received. The baking apparatus (e.g., baking apparatus 1000 of FIG. 10) may process one or more wafers before the notification (e.g., notification 136 of FIG. 10) that the process chamber (e.g., process chamber 102 of FIG. 10) has entered the idle state is received. In some embodiments when the baking apparatus (e.g., baking apparatus 1000 of FIG. 10) processes multiple wafers, the multiple wafers may belong to a same batch or different batches.

In response to determining at operation 1102 that the notification (e.g., notification 136 of FIG. 10) that the process chamber (e.g., process chamber 102 of FIG. 10) has entered the idle state is received, method 1100 proceeds to operation 1104. In operation 1104, the processor (e.g., processor 122 of FIG. 10) of the controller (e.g., controller 120 of FIG. 10) receives a signal (e.g., signal 604 of FIG. 10) from a gas sensor (e.g., gas sensor 602 of FIG. 10). In operation 1106, the processor (e.g., processor 122 of FIG. 10) of the controller (e.g., controller 120 of FIG. 10) determines a concentration (e.g., concentration 606 of FIG. 10) of process byproduct chemicals in an outgoing gas (e.g., outgoing gas 116B of FIG. 10) based on the signal (e.g., signal 604 of FIG. 10).

In operation 1108, the processor (e.g., processor 122 of FIG. 10) of the controller (e.g., controller 120 of FIG. 10) determines whether the concentration (e.g., concentration 606 of FIG. 10) is greater than a threshold concentration (e.g., threshold concentration 608 of FIG. 10). In response to determining at operation 1108 that the concentration (e.g., concentration 606 of FIG. 10) is greater than the threshold concentration (e.g., threshold concentration 608 of FIG. 10), method 1100 proceeds to operation 1104. In some embodiments, operations 1104-1108 may be repeated one or more times until the concentration (e.g., concentration 606 of FIG. 10) is less than or equal to the threshold concentration (e.g., threshold concentration 608 of FIG. 10).

In response to determining at operation 1108 that the concentration (e.g., concentration 606 of FIG. 10) is less than or equal to the threshold concentration (e.g., threshold concentration 608 of FIG. 10), method 1100 proceeds to operation 1110. In operation 1110, the processor (e.g., processor 122 of FIG. 10) of the controller (e.g., controller 120 of FIG. 10) determines that an LFR mode can be started. In operation 1112, the processor (e.g., processor 122 of FIG. 10) of the controller (e.g., controller 120 of FIG. 10) sends an instruction (e.g., instruction 814 of FIG. 10) to a first valve (e.g., valve 802 of FIG. 10) to set a flow rate of an incoming gas (e.g., incoming gas 116A of FIG. 10) to an idle IFR (e.g., idle IFR 806 of FIG. 10). In operation 1114, the processor (e.g., processor 122 of FIG. 10) of the controller (e.g., controller 120 of FIG. 10) sends an instruction (e.g., instruction 818 of FIG. 10) to a second valve (e.g., valve 804 of FIG. 10) to set a flow rate of a bypass gas (e.g., bypass gas 116C of FIG. 10) to an idle BFR (e.g., idle BFR 808 of FIG. 10).

In operation 1116, the processor (e.g., processor 122 of FIG. 10) of the controller (e.g., controller 120 of FIG. 10) determines whether a notification (e.g., notification 138 of FIG. 10) that the baking apparatus (e.g., baking apparatus 1000 of FIG. 10) has entered an active state is received. In some embodiments, the processor (e.g., processor 122 of FIG. 10) of the controller (e.g., controller 120 of FIG. 10) may receive the notification (e.g., notification 138 of FIG. 10) from the process chamber (e.g., process chamber 102 of FIG. 10) of the baking apparatus (e.g., baking apparatus 1000 of FIG. 10). In some embodiments, operation 1116 may be repeated one or more times until the notification (e.g., notification 138 of FIG. 10) that the baking apparatus (e.g., baking apparatus 1000 of FIG. 10) has entered the active state is received.

In response to determining at operation 1116 that the notification (e.g., notification 138 of FIG. 10) that the baking apparatus (e.g., baking apparatus 1000 of FIG. 10) has entered the active state is received, method 1100 proceeds to operation 1118. In operation 1118, the processor (e.g., processor 122 of FIG. 10) of the controller (e.g., controller 120 of FIG. 10) determines that an HFR mode can be started. In operation 1120, the processor (e.g., processor 122 of FIG. 10) of the controller (e.g., controller 120 of FIG. 10) sends an instruction (e.g., instruction 816 of FIG. 10) to the first valve (e.g., valve 802 of FIG. 10) to set the flow rate of the incoming gas (e.g., incoming gas 116A of FIG. 10) to a process IFR (e.g., process IFR 810 of FIG. 10). In operation 1122, the processor (e.g., processor 122 of FIG. 10) of the controller (e.g., controller 120 of FIG. 10) sends an instruction (e.g., instruction 820 of FIG. 10) to the second valve (e.g., valve 804 of FIG. 10) to set the flow rate of the bypass gas (e.g., bypass gas 116C of FIG. 10) to a process BFR (e.g., process BFR 812 of FIG. 10). In some embodiments, after performing operation 1122, method 1100 proceeds to end. In other embodiments, after performing operation 1122, method 1100 proceeds to operation 1102. In such embodiments, operations 1102-1122 of method 1100 may be performed in a loop.

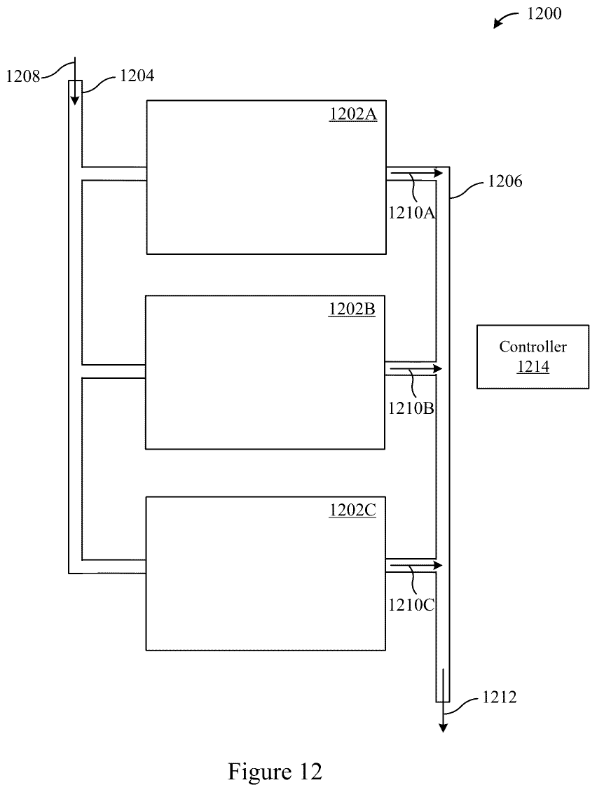

FIG. 12 is a schematic view of a baking apparatus 1200 in accordance with various embodiments. The baking apparatus 1200 may comprise a plurality of baking apparatuses 1202A, 1202B, and 1202C. In some embodiments, each of the baking apparatuses 1202A, 1202B, and 1202C may be implemented by the baking apparatuses 800 or 1000 (see FIGS. 8 and 10). The baking apparatuses 1202A, 1202B, and 1202C are coupled to an intake conduit 1204 and an exhaust conduit 1206. The intake conduit 1204 is configured to accept an intake gas 1208 and divert the intake gas 1208 to the baking apparatuses 1202A, 1202B, and 1202C. The exhaust conduit 1206 is configured to accept exhaust gases 1210A, 1210B, and 1210C from the baking apparatuses 1202A, 1202B, and 1202C, respectively. The exhaust conduit 1206 is further configured to provide a combined exhaust gas 1212 comprising the exhaust gases 1210A, 1210B, and 1210C to a facility exhaust system. In the illustrated embodiment, a flow rate of combined exhaust gas 1212 remains unchanged when switching between HFR and LFR modes.

In some embodiments, the baking apparatuses 1202A, 1202B, and 1202C comprise individual controllers (e.g., controller 120 of FIG. 1A). In other embodiments, the baking apparatuses 1202A, 1202B, and 1202C may not comprise individual controllers. In such embodiments, the baking apparatus 1200 comprises a single controller 1214 that is configured to control each of the baking apparatuses 1202A, 1202B, and 1202C. The single controller 1214 may be similar to the controller 120 (see FIG. 1A) and the description is not repeated herein. In the illustrated embodiments, the baking apparatus 1200 comprises three baking apparatuses 1202A, 1202B, and 1202C. In other embodiments, the baking apparatus 1200 may comprise more than three or less than three baking apparatuses.

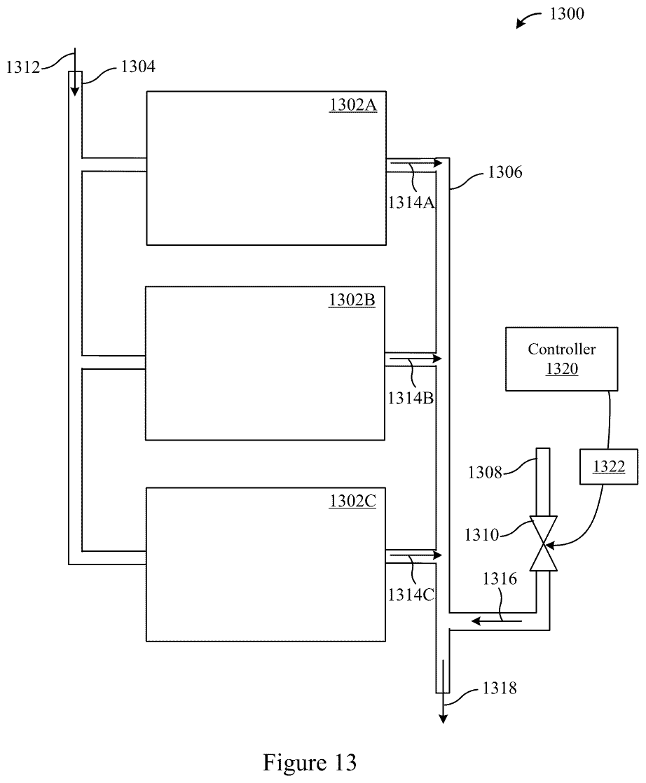

FIG. 13 is a schematic view of a baking apparatus 1300 in accordance with various embodiments. The baking apparatus 1300 may comprise a plurality of baking apparatuses 1302A, 1302B, and 1302C. In some embodiments, each of the baking apparatuses 1302A, 1302B, and 1302C may be implemented by the baking apparatuses 100A, 100B, 600A, 600B, 800 or 1000 (see FIGS. 1A, 1B, 6A, 6B, 8, and 10) such that at least one of the baking apparatuses 1302A, 1302B, and 1302C is implemented by baking apparatuses 100A, 100B, 600A, or 600B (see FIGS. 1A, 1B, 6A, and 6B). For example, each of the baking apparatuses 1302A and 1302B may be implemented by the baking apparatuses 800 or 1000 (see FIGS. 8 and 10) and the baking apparatuses 1302C may be implemented by baking apparatuses 100A, 100B, 600A, or 600B (see FIGS. 1A, 1B, 6A, and 6B). In such embodiments, flow rates of the exhaust gases 1314A and 1314B remain unchanged when switching between HFR and LFR modes and a flow rate of the exhaust gas 1314C changes when switching between HFR and LFR modes.

The baking apparatuses 1302A, 1302B, and 1302C are coupled to an intake conduit 1304 and an exhaust conduit 1306. The intake conduit 1304 is configured to accept an intake gas 1312 and divert the intake gas 1312 to the baking apparatuses 1302A, 1302B, and 1302C. The exhaust conduit 1306 is configured to accept exhaust gases 1314A, 1314B, and 1314C from the baking apparatuses 1302A, 1302B, and 1302C, respectively. The baking apparatus 1300 further includes a conduit 1308 that is coupled to the exhaust conduit 1306.

In some embodiments, a valve 1310 may be coupled to the conduit 1308. The valve 1310 may be configured to control a flow of a gas through the conduit 1308. The valve 1310 may comprise a check valve, a flow control valve, or any suitable valve. The valve 1310 may be an electronically controlled valve that may be opened or closed in response to receiving signals from a controller 1320. In some embodiments, the valve 1310 is configured provide a facility gas 1316 to the exhaust conduit 1306 and change a flow rate of the facility gas 1316. In some embodiments, the facility gas 1316 may comprise a facility air. The exhaust conduit 1306 may be further configured to provide a mixture of the exhaust gases 1314A-1314C and the facility gas 1316 to an exhaust of a fabrication facility as a combined exhaust gas 1318. In some embodiments when the baking apparatus 1302C switches from the HFR mode to the LFR mode, the controller 1320 sends a notification 1322 to the valve 1310 to set a flow rate of the facility gas 1316 to a desired flow rate. In some embodiments, the desired flow rate of the facility gas 1316 is such that a flow rate of the combined exhaust gas 1318 remains unchanged when switching between HFR and LFR modes.

In some embodiments, the baking apparatuses 1302A, 1302B, and 1302C comprise individual controllers (e.g., controller 120 of FIG. 1A). In such embodiments, the controller 1320 may be configured to control the valve 1310. In other embodiments, the baking apparatuses 1302A, 1302B, and 1302C may not comprise individual controllers. In such embodiments, the baking apparatus 1300 comprises the single controller 1320 that is configured to control each of the baking apparatuses 1302A, 1302B, and 1302C and the valve 1310. The single controller 1320 may be similar to the controller 120 (see FIG. 1A) and the description is not repeated herein. In yet other embodiments when the baking apparatuses 1302A, 1302B, and 1302C comprise individual controllers (e.g., controller 120 of FIG. 1A), the controller 1320 may be omitted. In such embodiments, the individual controllers (e.g., controller 120 of FIG. 1A) may be also configured to control the valve 1310. In the illustrated embodiments, the baking apparatus 1300 comprises three baking apparatuses 1302A, 1302B, and 1302C. In other embodiments, the baking apparatus 1300 may comprise more than three or less than three baking apparatuses.

Example embodiments of the disclosure are described below. Other embodiments can also be understood from the entirety of the specification as well as the claims filed herein.

Example 1. An apparatus including a process chamber, a hot plate within the process chamber, and a first valve coupled to the process chamber. The first valve is configured to control a flow rate of an incoming gas entering the process chamber. The incoming gas includes a first portion of a supply gas. The apparatus further includes a controller operably coupled to the process chamber and the first valve. The controller includes a memory configured to store a process incoming flow rate and an idle incoming flow rate. The idle incoming flow rate is less than the process incoming flow rate. The controller further includes a processor operably coupled to the memory. The processor is configured to receive a first notification that the process chamber entered an idle state, determine that a low-flow-rate (LFR) mode can be started, send a first instruction to the first valve to set the flow rate of the incoming gas to the idle incoming flow rate, receive a second notification that the process chamber entered an active state, determine that a high-flow-rate (HFR) mode can be started, and send a second instruction to the first valve to set the flow rate of the incoming gas to the process incoming flow rate.

Example 2. The apparatus of example 1, where: the memory is further configured to store a threshold time; and determining that the LFR mode can be started includes: determining a time that passed since the process chamber entered the idle state; and determining that the time is equal to the threshold time.

Example 3. The apparatus of one of examples 1 and 2, further including a gas sensor coupled to the process chamber, the gas sensor being configured to sense a concentration of process byproduct chemicals in an outgoing gas leaving the process chamber, where: the memory is further configured to store a threshold concentration; and determining that the LFR mode can be started includes: receiving a signal from the gas sensor; determining the concentration of the process byproduct chemicals the outgoing gas based on the signal; and determining that the concentration is less than or equal to the threshold concentration.

Example 4. The apparatus of one of examples 1 to 3, further including: a second valve coupled to the process chamber, the second valve being configured to control a flow rate of a bypass gas bypassing the process chamber, the bypass gas including a second portion of the supply gas, where: the memory is further configured to store: a process bypass flow rate; and an idle bypass flow rate, where the idle bypass flow rate is greater than the process bypass flow rate; and the processor is further configured to: after determining that the LFR mode can be started, send a third instruction to the second valve to set the flow rate of the bypass gas to the idle bypass flow rate; and after determining that the HFR mode can be started, send a fourth instruction to the second valve to set the flow rate of the bypass gas to the process bypass flow rate.

Example 5. The apparatus of one of examples 1 to 4, where a sum of the process incoming flow rate and the process bypass flow rate is equal to a sum of the idle incoming flow rate and the idle bypass flow rate.

Example 6. The apparatus of one of examples 1 to 5, further including: a support platform within the process chamber, where the hot plate is placed on a front side of the support platform; and a back plate attached to a backside of the support platform, where the back plate comprises a void under a vacuum condition.

Example 7. The apparatus of one of examples 1 to 6, further including: an exhaust conduit coupled to the process chamber, the exhaust conduit being configured to accept an outgoing gas from the chamber; and a second valve coupled to the exhaust conduit, the second valve being configured to control a flow rate of a facility gas into the exhaust conduit, where the processor is further configured to, after determining that the LFR mode can be started, send a third instruction to the second valve to set the flow rate of the facility gas to a desired flow rate.

Example 8. An apparatus including a first baking apparatus. The first baking apparatus includes a first process chamber, a first hot plate within the first process chamber, and a first valve coupled to the first process chamber. The first valve is configured to control a flow rate of a first incoming gas entering the first process chamber. The first incoming gas includes a first portion of a first supply gas. The first baking apparatus further includes a first controller operably coupled to the first process chamber and the first valve. The first controller is configured to receive a first notification that the first process chamber entered a first idle state, determine a first time that passed since the first process chamber entered the first idle state, and in response to determining that the first time is equal to a first threshold time: determine that a first low-flow-rate (LFR) mode can be started, send a first instruction to the first valve to set the flow rate of the first incoming gas to a first idle incoming flow rate, receive a second notification that the first process chamber entered a first active state, determine that a first high-flow-rate (HFR) mode can be started, and send a second instruction to the first valve to set the flow rate of the first incoming gas to a first process incoming flow rate. The apparatus further includes a second baking apparatus. The second baking apparatus includes a second process chamber, a second hot plate within the second process chamber, and a second valve coupled to the second process chamber. The second valve is configured to control a flow rate of a second incoming gas entering the second process chamber. The second incoming gas includes a first portion of a second supply gas. The second baking apparatus further includes a gas sensor coupled to the second process chamber. The gas sensor is configured to detect a concentration of process byproduct chemicals in a second outgoing gas leaving the second process chamber. The second baking apparatus further includes a second controller operably coupled to the second process chamber, the second valve and the gas sensor. The second controller is configured to receive a third notification that the second process chamber entered a second idle state, receive a signal from the gas sensor, determine the concentration of the process byproduct chemicals the second outgoing gas based on the signal, in response to determining that the concentration is less than or equal to a threshold concentration: determine that a second LFR mode can be started, send a third instruction to the second valve to set the flow rate of the second incoming gas to a second idle incoming flow rate, receive a fourth notification that the second process chamber entered a second active state; determine that a second HFR mode can be started; and send a fourth instruction to the second valve to set the flow rate of the second incoming gas to a second process incoming flow rate.

Example 9. The apparatus of example 8, where: the first process incoming flow rate is greater than the first idle incoming flow rate; and the second process incoming flow rate is greater than the second idle incoming flow rate.

Example 10. The apparatus of one of examples 8 and 9, where the first baking apparatus further includes: a third valve coupled to the first process chamber, the third valve being configured to control a flow rate of a first bypass gas bypassing the first process chamber, the first bypass gas including a second portion of the first supply gas, where the first controller is further configured to: after determining that the first LFR mode can be started, send a fifth instruction to the third valve to set the flow rate of the first bypass gas to a first idle bypass flow rate; and after determining that the first HFR mode can be started, send a sixth instruction to the third valve to set the flow rate of the first bypass gas to a first process bypass flow rate.

Example 11. The apparatus of one of examples 8 to 10, where the first process bypass flow rate is less than the first idle bypass flow rate.

Example 12. The apparatus of one of examples 8 to 11, where the second baking apparatus further includes: a fourth valve coupled to the second process chamber, the fourth valve being configured to control a flow rate of a second bypass gas bypassing the second process chamber, the second bypass gas comprising a second portion of the second supply gas, where the second controller is further configured to: after determining that the second LFR mode can be started, send a seventh instruction to the fourth valve to set the flow rate of the second bypass gas to a second idle bypass flow rate; and after determining that the second HFR mode can be started, send an eighth instruction to the fourth valve to set the flow rate of the second bypass gas to a second process bypass flow rate.

Example 13. The apparatus of one of examples 8 to 12, where the second process bypass flow rate is less than the second idle bypass flow rate.

Example 14. The apparatus of one of examples 8 to 13, where: a sum of the first process incoming flow rate and the first process bypass flow rate is equal to a sum of the first idle incoming flow rate and the first idle bypass flow rate; and a sum of the second process incoming flow rate and the second process bypass flow rate is equal to a sum of the second idle incoming flow rate and the second idle bypass flow rate.

Example 15. A method including receiving a first notification that a process chamber of a baking apparatus entered an idle state, determining that a low-flow-rate (LFR) mode can be started, and providing an incoming gas to the process chamber. The incoming gas includes a first portion of a supply gas. The method further includes setting a flow rate of the incoming gas to an idle incoming flow rate, receiving a second notification that the process chamber entered an active state, determining that a high-flow-rate (HFR) mode can be started, and setting the flow rate of the incoming gas to a process incoming flow rate. The process incoming flow rate is greater than the idle incoming flow rate.

Example 16. The method of example 15, where determining that the LFR mode can be started includes: determining a time that passed since the process chamber entered the idle state; and determining that the time is equal to a threshold time.

Example 17. The method of one of examples 15 and 16, where determining that the LFR mode can be started includes: receiving a signal from a gas sensor coupled to the process chamber, where the gas sensor is configured to sense a concentration of process byproduct chemicals in an outgoing gas leaving the process chamber; determining the concentration of the process byproduct chemicals the outgoing gas based on the signal; and determining that the concentration is less than or equal to a threshold concentration.

Example 18. The method of one of examples 15 to 17, further including: after determining that the LFR mode can be started, setting a flow rate of a bypass gas to an idle bypass flow rate, the bypass gas bypassing the process chamber and including a second portion of the supply gas; and after determining that the HFR mode can be started, setting the flow rate of the bypass gas to an process bypass flow rate, wherein the process bypass flow rate is less than the idle bypass flow rate.

Example 19. The method of one of examples 15 to 18, where a sum of the process incoming flow rate and the process bypass flow rate is equal to a sum of the idle incoming flow rate and the idle bypass flow rate.

Example 20. The method of one of examples 15 to 19, where the flow rate of the incoming gas is set by a first valve coupled to the process chamber and the flow rate of the bypass gas is set by a second valve coupled to the process chamber.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. An apparatus comprising:
a process chamber;
a hot plate within the process chamber;
a first valve coupled to the process chamber, the first valve being configured to control a flow rate of an incoming gas entering the process chamber, wherein the incoming gas comprises a first portion of a supply gas;
a controller operably coupled to the process chamber and the first valve, the controller comprising:
a memory configured to store:
a process incoming flow rate; and
an idle incoming flow rate, wherein the idle incoming flow rate is less than the process incoming flow rate; and
a processor operably coupled to the memory, the processor configured to:
receive a first notification that the process chamber entered an idle state;
determine that a low-flow-rate (LFR) mode can be started;
send a first instruction to the first valve to set the flow rate of the incoming gas to the idle incoming flow rate;
receive a second notification that the process chamber entered an active state;
determine that a high-flow-rate (HFR) mode can be started; and
send a second instruction to the first valve to set the flow rate of the incoming gas to the process incoming flow rate.

2. The apparatus of claim 1, wherein:
the memory is further configured to store a threshold time; and
determining that the LFR mode can be started comprises:
determining a time that passed since the process chamber entered the idle state; and
determining that the time is equal to the threshold time.

3. The apparatus of claim 1, further comprising a gas sensor coupled to the process chamber, the gas sensor being configured to sense a concentration of process byproduct chemicals in an outgoing gas leaving the process chamber, wherein:
the memory is further configured to store a threshold concentration; and
determining that the LFR mode can be started comprises:
receiving a signal from the gas sensor;
determining the concentration of the process byproduct chemicals the outgoing gas based on the signal; and
determining that the concentration is less than or equal to the threshold concentration.

4. The apparatus of claim 1, further comprising:
a second valve coupled to the process chamber, the second valve being configured to control a flow rate of a bypass gas bypassing the process chamber, the bypass gas comprising a second portion of the supply gas, wherein:
the memory is further configured to store:
a process bypass flow rate; and
an idle bypass flow rate, wherein the idle bypass flow rate is greater than the process bypass flow rate; and
the processor is further configured to:
after determining that the LFR mode can be started, send a third instruction to the second valve to set the flow rate of the bypass gas to the idle bypass flow rate; and
after determining that the HFR mode can be started, send a fourth instruction to the second valve to set the flow rate of the bypass gas to the process bypass flow rate.

5. The apparatus of claim 4, wherein a sum of the process incoming flow rate and the process bypass flow rate is equal to a sum of the idle incoming flow rate and the idle bypass flow rate.

6. The apparatus of claim 1, further comprising:
a support platform within the process chamber, wherein the hot plate is placed on a front side of the support platform; and
a back plate attached to a backside of the support platform, wherein the back plate comprises a void under a vacuum condition.

7. The apparatus of claim 1, further comprising:
an exhaust conduit coupled to the process chamber, the exhaust conduit being configured to accept an outgoing gas from the chamber; and
a second valve coupled to the exhaust conduit, the second valve being configured to control a flow rate of a facility gas into the exhaust conduit, wherein the processor is further configured to, after determining that the LFR mode can be started, send a third instruction to the second valve to set the flow rate of the facility gas to a desired flow rate.

8. An apparatus comprising:
a first baking apparatus, wherein the first baking apparatus comprises:
a first process chamber;
a first hot plate within the first process chamber;
a first valve coupled to the first process chamber, the first valve being configured to control a flow rate of a first incoming gas entering the first process chamber, the first incoming gas comprising a first portion of a first supply gas;
a first controller operably coupled to the first process chamber and the first valve, wherein the first controller is configured to:
receive a first notification that the first process chamber entered a first idle state;
determine a first time that passed since the first process chamber entered the first idle state; and
in response to determining that the first time is equal to a first threshold time:
determine that a first low-flow-rate (LFR) mode can be started;
send a first instruction to the first valve to set the flow rate of the first incoming gas to a first idle incoming flow rate;
receive a second notification that the first process chamber entered a first active state;
determine that a first high-flow-rate (HFR) mode can be started; and
send a second instruction to the first valve to set the flow rate of the first incoming gas to a first process incoming flow rate; and
a second baking apparatus, wherein the second baking apparatus comprises:
a second process chamber;
a second hot plate within the second process chamber;
a second valve coupled to the second process chamber, the second valve being configured to control a flow rate of a second incoming gas entering the second process chamber, the second incoming gas comprising a first portion of a second supply gas;
a gas sensor coupled to the second process chamber, the gas sensor being configured to detect a concentration of process byproduct chemicals in a second outgoing gas leaving the second process chamber; and
a second controller operably coupled to the second process chamber, the second valve and the gas sensor, wherein the second controller is configured to:
receive a third notification that the second process chamber entered a second idle state;
receive a signal from the gas sensor;
determine the concentration of the process byproduct chemicals the second outgoing gas based on the signal; and
in response to determining that the concentration is less than or equal to a threshold concentration:
determine that a second LFR mode can be started;
send a third instruction to the second valve to set the flow rate of the second incoming gas to a second idle incoming flow rate;
receive a fourth notification that the second process chamber entered a second active state;
determine that a second HFR mode can be started; and
send a fourth instruction to the second valve to set the flow rate of the second incoming gas to a second process incoming flow rate.

9. The apparatus of claim 8, wherein:
the first process incoming flow rate is greater than the first idle incoming flow rate; and
the second process incoming flow rate is greater than the second idle incoming flow rate.

10. The apparatus of claim 8, wherein the first baking apparatus further comprises:
a third valve coupled to the first process chamber, the third valve being configured to control a flow rate of a first bypass gas bypassing the first process chamber, the first bypass gas comprising a second portion of the first supply gas, wherein the first controller is further configured to:
after determining that the first LFR mode can be started, send a fifth instruction to the third valve to set the flow rate of the first bypass gas to a first idle bypass flow rate; and
after determining that the first HFR mode can be started, send a sixth instruction to the third valve to set the flow rate of the first bypass gas to a first process bypass flow rate.

11. The apparatus of claim 10, wherein the first process bypass flow rate is less than the first idle bypass flow rate.

12. The apparatus of claim 10, wherein the second baking apparatus further comprises:
a fourth valve coupled to the second process chamber, the fourth valve being configured to control a flow rate of a second bypass gas bypassing the second process chamber, the second bypass gas comprising a second portion of the second supply gas, wherein the second controller is further configured to:
after determining that the second LFR mode can be started, send a seventh instruction to the fourth valve to set the flow rate of the second bypass gas to a second idle bypass flow rate; and
after determining that the second HFR mode can be started, send an eighth instruction to the fourth valve to set the flow rate of the second bypass gas to a second process bypass flow rate.

13. The apparatus of claim 12, wherein the second process bypass flow rate is less than the second idle bypass flow rate.

14. The apparatus of claim 12, wherein:
a sum of the first process incoming flow rate and the first process bypass flow rate is equal to a sum of the first idle incoming flow rate and the first idle bypass flow rate; and
a sum of the second process incoming flow rate and the second process bypass flow rate is equal to a sum of the second idle incoming flow rate and the second idle bypass flow rate.

15. A method comprising:
receiving a first notification that a process chamber of a baking apparatus entered an idle state;
determining that a low-flow-rate (LFR) mode can be started;
providing an incoming gas to the process chamber, wherein the incoming gas comprises a first portion of a supply gas;
setting a flow rate of the incoming gas to an idle incoming flow rate;
receiving a second notification that the process chamber entered an active state;
determining that a high-flow-rate (HFR) mode can be started; and
setting the flow rate of the incoming gas to a process incoming flow rate, wherein the process incoming flow rate is greater than the idle incoming flow rate.

16. The method of claim 15, wherein determining that the LFR mode can be started comprises:
determining a time that passed since the process chamber entered the idle state; and
determining that the time is equal to a threshold time.

17. The method of claim 15, wherein determining that the LFR mode can be started comprises: receiving a signal from a gas sensor coupled to the process chamber, wherein the gas sensor is configured to sense a concentration of process byproduct chemicals in an outgoing gas leaving the process chamber;
determining the concentration of the process byproduct chemicals the outgoing gas based on the signal; and
determining that the concentration is less than or equal to a threshold concentration.

18. The method of claim 15, further comprising:
after determining that the LFR mode can be started, setting a flow rate of a bypass gas to an idle bypass flow rate, the bypass gas bypassing the process chamber and comprising a second portion of the supply gas; and
after determining that the HFR mode can be started, setting the flow rate of the bypass gas to an process bypass flow rate, wherein the process bypass flow rate is less than the idle bypass flow rate.

19. The method of claim 18, wherein a sum of the process incoming flow rate and the process bypass flow rate is equal to a sum of the idle incoming flow rate and the idle bypass flow rate.

20. The method of claim 18, wherein the flow rate of the incoming gas is set by a first valve coupled to the process chamber and the flow rate of the bypass gas is set by a second valve coupled to the process chamber.
